(19) United States
(12) Patent Application Publication
(10) Pub. No.: US 2012/0142177 A1
(43) Pub. Date: Jun. 7, 2012

(54) METHODS OF MANUFACTURING A WIRING STRUCTURE AND METHODS OF MANUFACTURING A SEMICONDUCTOR DEVICE

(76) Inventors: Jee-Yong Kim, Hwaseong-si (KR); Joon-Hee Lee, Seongnam-si (KR); Jeong-Hyuk Choi, Seongnam-si (KR); Jai-Hyuk Song, Seongnam-si (KR); Seung-Wan Hong, Seoul (KR); Hwa-Eon Shin, Suwon-si (KR); Jong-Hyun Park, Seoul (KR); Woo-Jung Kim, Seoul (KR); Jae-Sung Ahn, Suwon-si (KR); Jung-Hwan Lee, Seoul (KR)

(21) Appl. No.: 13/299,538

(22) Filed: Nov. 18, 2011

(30) Foreign Application Priority Data
Dec. 3, 2010 (KR) 10-2010-0122894
Dec. 27, 2010 (KR) 10-2010-0135619

(51) Int. Cl. H01L 21/28

(52) U.S. Cl. 438/585; 438/653; 257/E21.158

(57) ABSTRACT

A method of manufacturing a wiring structure and a semiconductor device, the method of manufacturing a wiring structure including forming a first insulating interlayer on a substrate; forming a contact plug in an opening in the first insulating interlayer; forming a second insulating interlayer on the contact plug and the first insulating interlayer; removing a portion of the second insulating interlayer to form an opening therethrough such that the opening exposes the contact plug; filling a portion of the opening to form a wiring such that the wiring is electrically connected to the contact plug; and forming a diffusion barrier layer pattern on the wiring such that the diffusion barrier layer pattern fills a remaining portion of the opening.

### CROSS-REFERENCE TO RELATED APPLICATIONS

Korean Patent Application No. 10-2010-0122894, filed on Dec. 3, 2010, in the Korean Intellectual Property Office, and entitled: “Wiring Structures, Methods of Manufacturing a Wiring Structure, and Methods of Manufacturing a Semiconductor Device,” and Korean Patent Application No. 10-2010-0135619, filed on Dec. 27, 2010, in the Korean Intellectual Property Office, and entitled: “Wiring Structures, Methods of Manufacturing a Wiring Structure, and Methods of Manufacturing a Semiconductor Device,” are incorporated by reference herein in their entirety.

### BACKGROUND

1. Field

Embodiments relate to wiring structures, methods of manufacturing a wiring structure, and methods of manufacturing a semiconductor device.

2. Description of the Related Art

A gate structure of a semiconductor device may include a silicon oxide layer.

For example, a dynamic random access memory (DRAM) device may have a gate insulation layer including silicon oxide; and a flash memory device may have a tunnel insulation layer including silicon oxide.

### SUMMARY

Embodiments are directed to wiring structures, methods of manufacturing a wiring structure, and methods of manufacturing a semiconductor device.

The embodiments may be realized by providing a method of manufacturing a wiring structure, the method including forming a first insulating interlayer on a substrate; forming a contact plug in an opening in the first insulating interlayer; forming a second insulating interlayer on the contact plug and the first insulating interlayer; removing a portion of the second insulating interlayer to form an opening therethrough such that the opening exposes the contact plug; filling a portion of the opening to form a wiring such that the wiring is electrically connected to the contact plug; and forming a diffusion barrier layer pattern on the wiring such that the diffusion barrier layer pattern fills a remaining portion of the opening.

The method may further include forming an etch stop layer on the contact plug and the first insulating interlayer prior to forming the second insulating interlayer, wherein forming the opening includes removing a portion of the etch stop layer.

Forming the wiring may include forming a wiring layer on the contact plug and the second insulating interlayer to fill the opening; planarizing the wiring layer until a top surface of the second insulating interlayer is exposed; and removing an upper portion of the wiring layer.

Forming the diffusion barrier layer pattern may include forming a diffusion barrier layer on the wiring and the second insulating interlayer to fill a remaining portion of the opening; and planarizing the diffusion barrier layer until a top surface of the second insulating interlayer is exposed.

The wiring may be formed using copper, and the diffusion barrier layer pattern may be formed using at least one selected from the group of silicon nitride, tantalum, titanium, tantalum nitride, and titanium nitride.

The embodiments may also be realized by providing a method of manufacturing a semiconductor device, the method including forming a gate structure on a substrate such that the gate structure includes a sequentially stacked gate insulation layer and a gate electrode; forming a first insulating interlayer on the substrate to cover the gate structure such that the first insulating interlayer includes hydrogen bonds therein; performing a first annealing process using a first annealing gas to remove hydrogen in the first insulating interlayer, the first annealing gas including no hydrogen; and performing a second annealing process using a second annealing gas to cure dangling bonds at an interface between the gate insulation layer and the substrate, the second annealing gas including hydrogen.

The first annealing process and the second annealing process may be performed at a temperature of about 200° C. to about 600° C.

The second annealing process may be performed at a temperature of about 400° C. to about 500° C.

The second annealing process may be performed at a temperature lower than a temperature at which the first annealing process is performed.

The second annealing gas may include hydrogen (H₂) gas or ammonia (NH₃) gas.

The first insulating interlayer may be formed using at least one selected from the group of borosilicate glass, borophospho silicate glass, undoped silicate glass, spin on glass, flowable oxide, high density plasma oxide, and high-temperature oxide.

The embodiments may also be realized by providing a method of manufacturing a wiring structure, the method including forming a first insulating interlayer on a substrate; forming an opening in the first insulating interlayer; forming a contact plug in the opening in the first insulating interlayer; forming a second insulating interlayer on the contact plug and the first insulating interlayer; forming an opening in the second insulating interlayer by removing a portion of the second insulating interlayer such that the opening exposes the contact plug; forming a wiring by filling a portion of the opening such that the wiring is electrically connected to the contact plug; forming a diffusion barrier layer pattern on the wiring such that the diffusion barrier layer pattern fills a remaining portion of the opening, wherein forming the diffusion barrier layer pattern includes forming a diffusion barrier layer on the second insulating interlayer and on the wiring, and removing portions of the diffusion barrier layer on the second insulating interlayer and on the wiring such that a top surface of the diffusion barrier layer pattern is substantially coplanar with a top surface of the second insulating interlayer; and removing residual hydrogen in the first and second insulating interlayers by performing a heat treatment process on the substrate including the first and second insulating interlayers thereon.

The wiring may be formed using copper, and the diffusion barrier layer pattern may be formed using at least one selected from the group of silicon nitride, tantalum, titanium, tantalum nitride, and titanium nitride.

The diffusion barrier layer pattern may only be on the wiring.

The method may further include performing another heat treatment process, wherein the other heat treatment process includes a furnace annealing process, a thermal annealing process, a bake annealing process, a laser annealing process, or a rapid annealing process.

### BRIEF DESCRIPTION OF THE DRAWINGS

The embodiments will become apparent to those of ordinary skill in the art by describing in detail exemplary embodiments with reference to the attached drawings, in which:

FIG. 1 illustrates a cross-sectional view of a wiring structure according to an embodiment;

FIGS. 2 to 7 illustrate cross-sectional views of stages in a method of manufacturing the wiring structure of FIG. 1;

FIG. 8 illustrates a cross-sectional view of a semiconductor device according to an embodiment;

FIGS. 9 to 13 illustrate cross-sectional views illustrating a method of manufacturing the semiconductor device of FIG. 8;

FIG. 14 illustrates a cross-sectional view of a semiconductor device according to another embodiment;

FIGS. 15 to 19 illustrate cross-sectional views of stages in a method of manufacturing the semiconductor device of FIG. 14;

FIGS. 20 to 26 illustrate cross-sectional views of stages in a method of manufacturing a semiconductor device according to another embodiment;

FIGS. 27 to 32 illustrate cross-sectional views of stages in a method of manufacturing a semiconductor device according to yet another embodiment;

FIGS. 33 to 38 illustrate cross-sectional views of stages in a method of manufacturing a semiconductor device according to still another embodiment; and

FIGS. 39 to 43 illustrate cross-sectional views of stages in a method of manufacturing a semiconductor device according to still another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element or layer is referred to as being “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

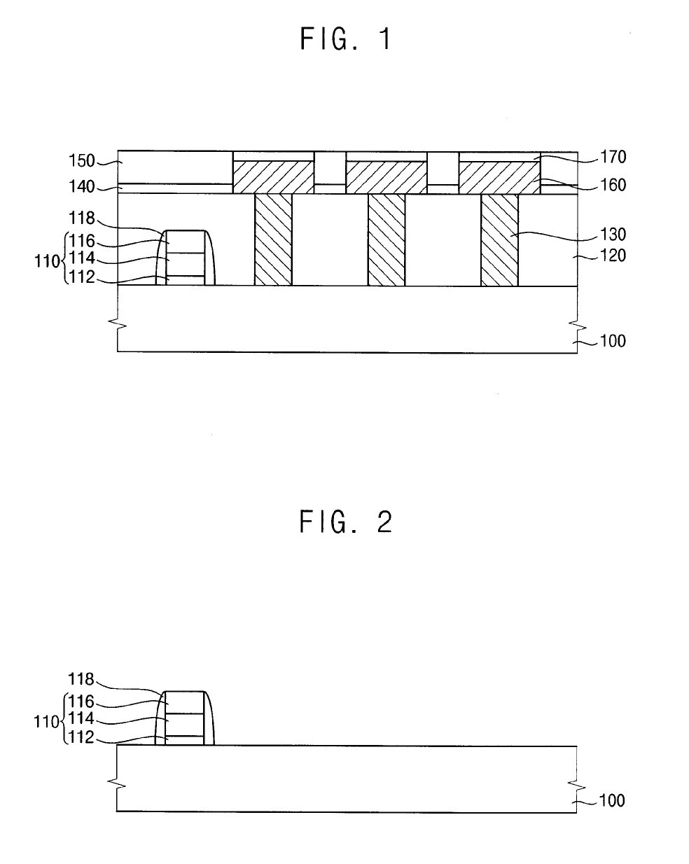

FIG. 1 illustrates a cross-sectional view of a wiring structure according to an embodiment.

Referring to FIG. 1, the wiring structure may include a contact plug 130, a wiring 160, and a diffusion barrier layer pattern 170 sequentially formed or stacked on a substrate 100.

The substrate 100 may include a silicon substrate, a germanium substrate, a silicon-germanium substrate, a silicon-on-insulator (SOI) substrate, a germanium-on-insulator (GOI) substrate, or the like. In an implementation, the substrate 100 may be a silicon substrate. An isolation layer (not shown) may be formed on the substrate 100 to define an active region and a field region. An impurity region (not shown) may be further formed at an upper portion of the substrate 100.

The contact plug 130 may be formed through a first insulating interlayer 120 on the substrate 100, and may be electrically connected to the impurity region. In an implementation, a plurality of contact plugs 130 may be formed. The contact plug 130 may include, e.g., doped polysilicon, a metal, and/or a metal silicide. The first insulating interlayer 120 may include, e.g., an oxide, a nitride and/or, an oxynitride.

A barrier layer (not shown) may be further formed on an outer sidewall of the contact plug 130. The barrier layer may include, e.g., a metal and/or a metal nitride.

The wiring 160 may partially fill an opening (not shown) through an etch stop layer 140 and a second insulating interlayer 150 sequentially stacked on the first insulating interlayer 120. The wiring 160 may be electrically connected to the contact plugs 130 (that are exposed by the opening). In an implementation, a plurality of wirings 160 may be formed to correspond to the plurality of contact plugs 130. The wiring 160 may include a metal, e.g., copper, aluminum, tungsten, or the like. The etch stop layer 140 may include, e.g., silicon nitride (SiN), silicon carbide (SiC), silicon oxynitride (SiON), or silicon oxycarbide (SiOC). The second insulating interlayer 150 may include an oxide, e.g., borosilicate glass (BSG), borophospho silicate glass (BPSG), undoped silicate glass (USG), spin on glass (SOG), flowable oxide (FOX), tetraethyl orthosilicate (TEOS), a high density plasma (HDP) oxide, or high-temperature oxide (HTO).

The diffusion barrier layer pattern 170 may be formed on the wiring 160 to fill remaining portions of the opening. Thus, a top surface of the diffusion barrier layer pattern 170 may be coplanar with a top surface of the second insulating interlayer 150. In an implementation, a plurality of diffusion barrier layer patterns 170 may be formed to correspond to the plurality of wirings 160. The diffusion barrier layer pattern 170 may include, e.g., silicon nitride, titanium, titanium nitride, titanium compound, ruthenium, tantalum, tantalum nitride, or tantalum compound.

A gate structure 110 may be formed on the substrate 100; and the gate structure 110 may be covered by the first insulating interlayer 120. The gate structure 110 may include a gate insulation layer pattern 112, a gate electrode 113, and a gate mask 116 sequentially stacked on the substrate 100. A gate spacer 118 may be further formed on a sidewall of the gate structure 110.

The wiring structure may include the diffusion barrier layer pattern 170 formed only on the wiring 160, e.g., the diffusion barrier layer pattern 170 may not entirely cover the second insulating interlayer 150. Thus, it may be easy to remove residual hydrogen in the first and second insulating interlayers 120 and 150 by a heat treatment process so that the gate insulation layer pattern 112 of the gate structure 110 may exhibit good interface characteristics. Also, a diffusion path via the diffusion barrier layer pattern 170 between the wirings 160 may be blocked so that electromigration between the wirings 160 may be prevented. Thus, a semiconductor device using the wiring structure may have good reliability.

For example, the wiring structure may include the contact plug 130 through the first insulating interlayer 120 on the substrate 100, the wiring 160 on the contact plug 130, the wiring 160 partially filling the opening through the second insulating interlayer 150, the second insulating interlayer 150 formed on the first insulating interlayer 120, and the diffusion barrier layer pattern 170 on the wiring 160, the diffusion barrier layer pattern 170 filling the remaining portion of the opening. The etch stop layer 140 may be further formed between the first insulating interlayer 120 and the second insulating interlayer 150. A portion of a sidewall of the wiring 160 may be surrounded by the etch stop layer 140. The diffusion barrier layer pattern 170 may include at least one selected from the group of silicon nitride, tantalum, titanium, tantalum nitride and titanium nitride. The second insulating interlayer 150 may include at least one selected from the group of BSG, BPSG, USG, SOG, FOX, TEOS, HDP oxide, and HTO

FIGS. 2 to 7 illustrate cross-sectional views of stages in a method of manufacturing the wiring structure of FIG. 1.

Referring to FIG. 2, a gate structure 110 may be formed on a substrate 100.

The substrate 100 may include, e.g., a silicon substrate, a germanium substrate, a silicon-germanium substrate, a silicon-on-insulator (SOI) substrate, a germanium-on-insulator (GOI) substrate, or the like. In an implementation, the substrate 100 may be a silicon substrate. An isolation layer (not shown) may be formed at an upper portion of the substrate 100 to define an active region and a field region.

A gate insulation layer, a gate conductive layer, and a gate mask layer (not shown) may be sequentially formed on the substrate 100. The gate mask layer, the gate conductive layer, and the gate insulation layer may be sequentially patterned to form the gate structure 110 including a gate insulation layer pattern 112, a gate electrode 114, and a gate mask 116, sequentially stacked on the substrate 100.

The gate insulation layer may be formed by performing a thermal oxidation process on a top surface of the substrate 100 (including silicon). In this case, dangling bonds may be generated at an interface between the substrate 100 and the gate insulation layer. The gate conductive layer may be formed using, e.g., doped polysilicon, a metal, and/or a metal silicide. The gate mask layer may be formed using, e.g., silicon nitride or silicon oxynitride.

The gate spacer 118 may be further formed on a sidewall of the gate structure 110. A gate spacer layer (not shown) may be formed on the substrate 100 to cover the gate structure 110; and the gate spacer layer may be anisotropically etched to form the gate spacer 118. The gate spacer 118 may be formed using, e.g., silicon nitride.

An impurity region (not shown) may be formed at an upper portion of the substrate 100 by an ion implantation process using the gate structure 110 and the gate spacer 118 as an ion implantation mask. Thus, a transistor including the gate structure 110 and the impurity region may be formed.

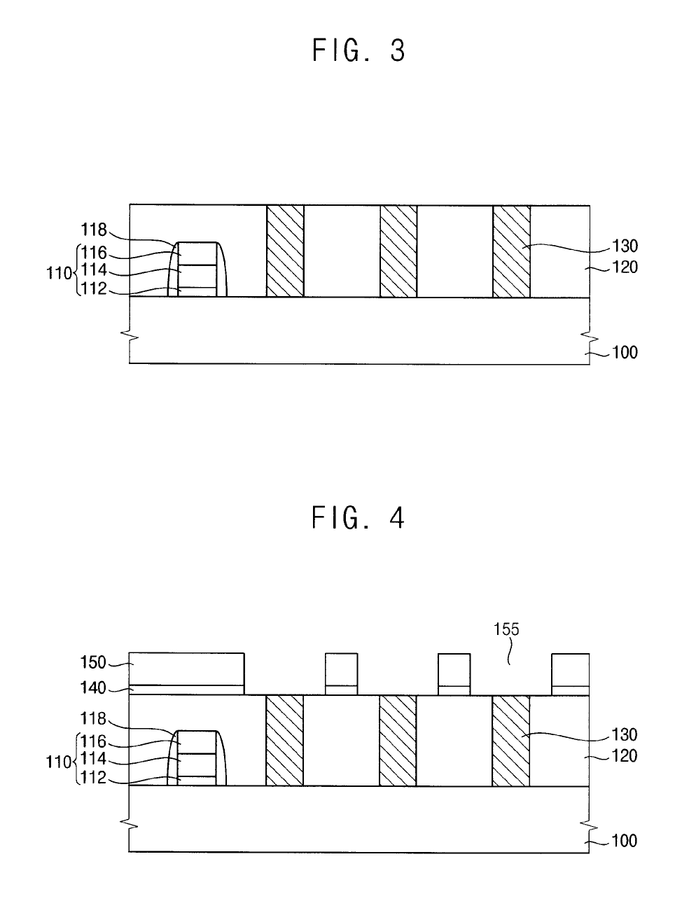

Referring to FIG. 3, a first insulating interlayer 120 may be formed on the substrate 100 to cover the gate structure 110. Then, a contact plug 130 may be formed through the first insulating interlayer 120.

The first insulating interlayer 120 may be formed using, e.g., an oxide, a nitride, and/or an oxynitride. The first insulating interlayer 120 may be formed by, e.g., a chemical vapor deposition (CVD) process or an atomic layer deposition (ALD) process.

The first insulating interlayer 120 may be partially removed to form a first opening (not shown) exposing the impurity region of the substrate 100. A first conductive layer (not shown) may be formed on the substrate 100 and the first insulating interlayer 120 to fill the first opening. An upper portion of the conductive layer may be planarized until a top surface of the first insulating interlayer 120 is exposed to form the contact plug 130. In an implementation, a plurality of first openings may be formed through the first insulating interlayer 120 and thus a plurality of contact plugs 130 may be formed therein.

For example, a photoresist pattern (not shown) may be formed on the first insulating interlayer 120; and the first insulating interlayer 120 may be etched using the photoresist pattern as an etching mask. The first conductive layer may be formed using, e.g., doped polysilicon, a metal, and/or a metal silicide. An upper portion of the first conductive layer may be planarized by a chemical mechanical polishing (CMP) process and/or an etch-back process.

A barrier layer (not shown) may be further formed on a sidewall of the first opening prior to forming the first conductive layer. The barrier layer may be formed using, e.g., a metal and/or a metal nitride.

Referring to FIG. 4, an etch stop layer 140 and a second insulating interlayer 150 may be sequentially formed on the first insulating interlayer 120 and the contact plug 130. A second opening 155 may be formed through the second insulating interlayer 150 and the etch stop layer 140 to expose the contact plug 130. In an implementation, a plurality of second opening 155 may be formed to expose the corresponding plurality of contact plugs 130.

The etch stop layer 140 may be formed using, e.g., silicon nitride (SiN), silicon carbide (SiC), silicon oxynitride (SiON), or silicon oxycarbide (SiOC). In an implementation, the etch stop layer 140 may be formed using silicon nitride, which may have an etching selectivity with respect to the first insulating interlayer 120 including silicon oxide.

The second insulating interlayer 150 may be formed using, e.g., silicon oxide. In an implementation, the second insulating interlayer 150 may be formed using borosilicate glass (BSG), borophospho silicate glass (BPSG), undoped silicate glass (USG), spin on glass (SOG), flowable oxide (FOX), tetraethyl orthosilicate (TEOS), high density plasma (HDP) oxide, or high-temperature oxide (HTO). The second insulating interlayer 150 may be formed by a CVD process or an ALD process. When the second insulating interlayer 150 is formed by a CVD process using silane (SiH₄) gas or TEOS (Si(C₂H_{S}O)₄) gas as a source gas, the second insulating interlayer 150 may include hydrogen bonds, e.g., Si—H, N-H, Si—OH, of which binding force is relatively weak. Thus, hydrogen atoms may easily migrate to the substrate 100 or the gate insulation layer pattern 112 through a surface of the contact plug 130 or a subsequently formed wiring so that the semiconductor device may have poor electrical characteristics.

A photoresist pattern (not shown) may be formed on the second insulating interlayer 150. The second insulating interlayer 150 and the etch stop layer 140 may be etched using the photoresist pattern as an etching mask until the contact plug 130 is exposed to form the second opening 155.

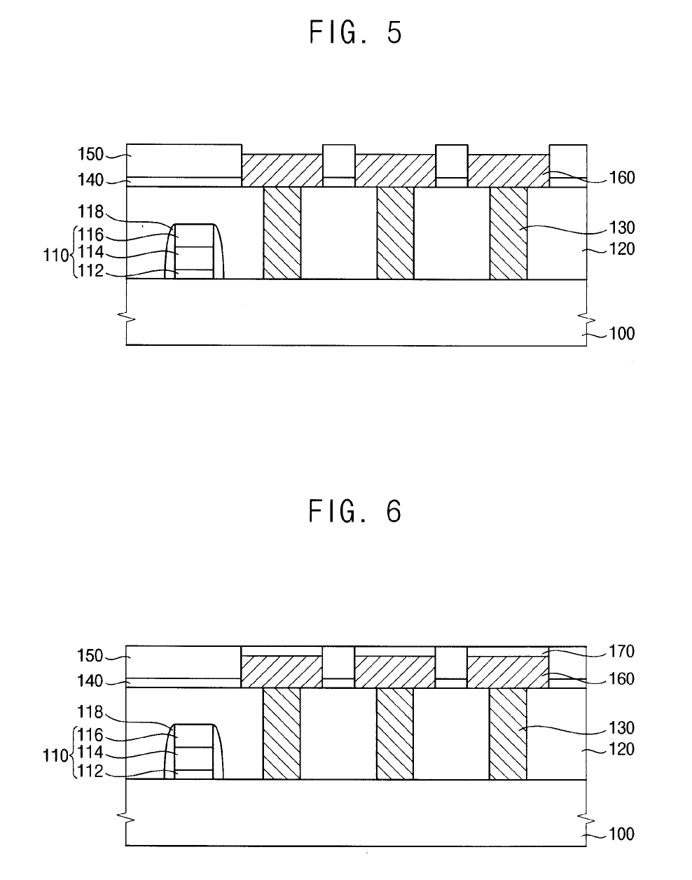

Referring to FIG. 5, the wiring 160 may be formed on the contact plug 130 and the first insulating interlayer 120 to partially fill the second opening 155. In an implementation, a plurality of wirings 160 may be formed in the corresponding plurality of second openings 155.

For example, a wiring layer (not shown) may be formed on the contact plug 130, the first insulating interlayer 120, and the second insulating interlayer 150 to fill the second opening 155. The wiring layer may planarized by a CMP process or an etch-back process until a top surface of the second insulating interlayer 150 is exposed. An upper portion of the planarized wiring layer in the second opening 155 may then be etched to form the wiring 160 partially filling the second opening. A top surface of the wiring 160 may be lower than the top surface of the second insulating interlayer 150. In an implementation, the upper portion of the wiring layer may be etched by a wet etching process or a dry etching process. For example, the wiring layer (including, e.g., copper) may be etched by a dry etching process using argon/chlorine plasma or a wet etching process using an etchant including nitric acid and sulfuric acid.

Referring to FIG. 6, a diffusion barrier layer pattern 170 may be formed on the wiring 160 to fill remaining portions of the second opening 155. In an implementation, a plurality of diffusion layer patterns 170 may be formed on the corresponding plurality of wirings 160.

For example, a diffusion barrier layer (not shown) may be formed on the wiring 160 and the second insulating interlayer 150 to fill the second opening 155. The diffusion barrier layer may then be planarized until the top surface of the second insulating interlayer 150 is exposed to form the diffusion barrier layer pattern 170. The diffusion barrier layer pattern 170 may be formed using, e.g., silicon nitride, titanium, titanium nitride, a titanium compound, ruthenium, tantalum, tantalum nitride, or a tantalum compound.

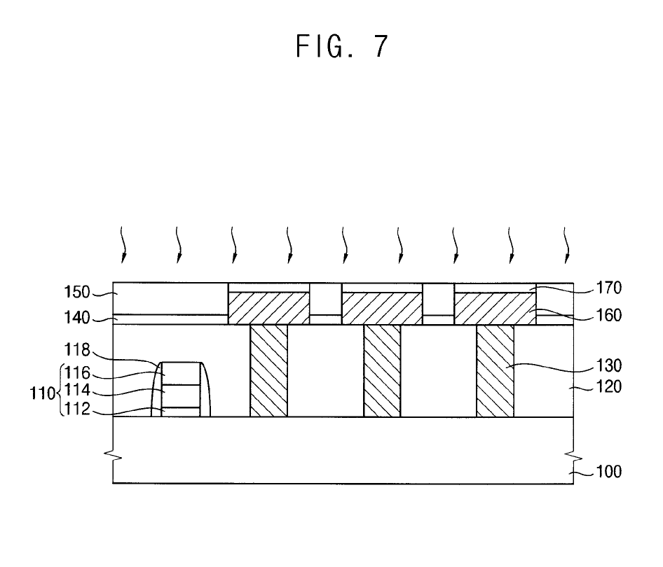

Referring to FIG. 7, a heat treatment process may be performed on the substrate 100 including the gate structure 110, the contact plug 130, the wiring 160, the diffusion barrier layer pattern 170, and the first and second insulating interlayers 120 and 150. In an implementation, the heat treatment process may be performed for about 1 to about 5 hours at a temperature of about 200° C. to about 600° C. The heat treatment process may be performed using an annealing gas including hydrogen. Residual hydrogen in the second insulating interlayer 150 may be removed; and dangling bonds generated at an interface between the substrate 100 and the gate insulation layer pattern 112 may be cured by the heat treatment process. By the above processes, the wiring structure may be manufactured.

The wiring structure may include the diffusion barrier layer pattern 170 formed only on the wiring 160, e.g., the diffusion barrier layer pattern 170 may not entirely cover the second insulating interlayer 150. Thus, it may be easy to remove residual hydrogen in the first and second insulating interlayers 120 and 150 by a heat treatment process so that the gate insulation layer pattern 112 of the gate structure 110 may have good interface characteristics. Also, a diffusion path via the diffusion barrier layer pattern 170 between the wirings 160 may be blocked so that electromigration between the wirings 160 may be reduced or prevented. Thus, a semiconductor device using the wiring structure may have good reliability.

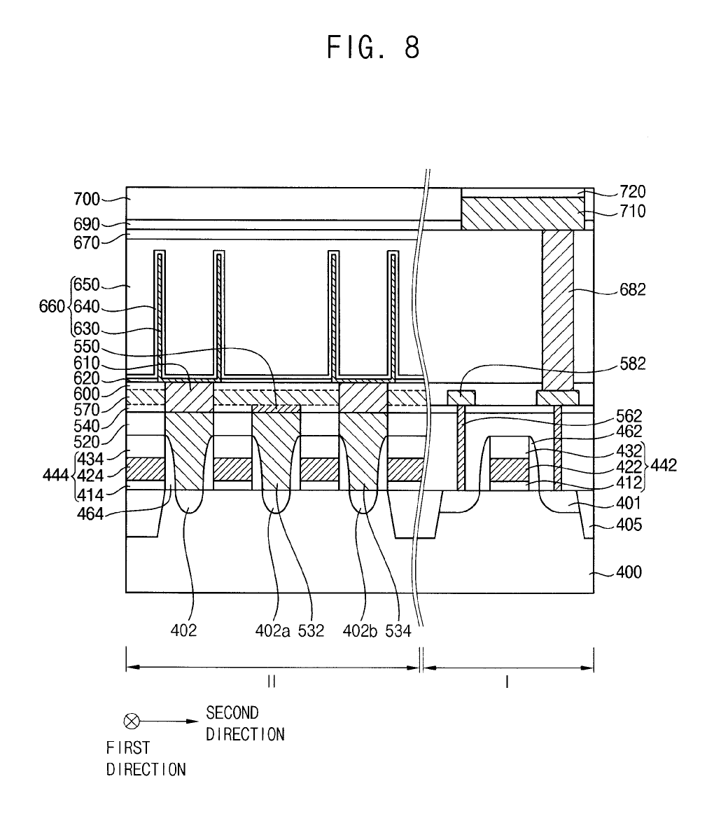

FIG. 8 illustrates a cross-sectional view of a semiconductor device according to an embodiment.

Referring to FIG. 8, the semiconductor device may include a first transistor and a wiring structure on a substrate 400 in a first region I and a second transistor and a capacitor 660 on the substrate 400 in a second region II. The semiconductor device may further include a bit line 570.

The first region I may be a peripheral circuit region and the second region II may be a cell region. The peripheral circuit region may further include an NMOS transistor region and a PMOS transistor region.

The first transistor may include a first gate structure 442 and a first impurity region 401 at an upper portion of the substrate 400 and adjacent to the first gate structure 442. The first gate structure 442 may include a first gate insulation layer pattern 412, a first gate electrode 422, and a first gate mask 432 sequentially stacked on the substrate 400. In an implementation, a plurality of first gate structures 442 may be spaced apart from each other in a second direction; and each of the first gate structures 442 may extend in a first direction substantially perpendicular to the second direction. A gate spacer 462 may be further formed on sidewalls of the gate structures 442.

The second transistor may include a second gate structure 444 and a second impurity region 402 at an upper portion of the substrate 400 adjacent to the second gate structure 444. The second impurity region 402 may include a first source/drain region 402a and a second source/drain region 402b. The second gate structure 444 may include a second gate insulation layer pattern 414, a second gate electrode 424, and a second gate mask 434 sequentially stacked on the substrate 400. In an implementation, a plurality of second gate structures 444 may be spaced apart from each other in the second direction; and each of the second gate structure 444 may extend in the first direction. A second spacer 464 may be further formed on sidewalls of the second gate structures 444.

The first and second transistors may be covered by a first insulating interlayer 520. Second to fourth insulating interlayers 540, 600, and 670 may be sequentially formed on the first insulating interlayer 520.

The capacitor 660 may be formed on the third insulating interlayer 600 in the second region II. The capacitor 660 may include a lower electrode 630, a dielectric layer 640, and an upper electrode 650.

The lower electrode 630 may be electrically connected to the second source/drain region 402b through a capacitor contact 610 and a second plug 534. The capacitor contact 610 may be formed in the second and third insulating interlayers 540 and 600; and the second plug 534 may be formed through the first insulating interlayer 520.

The bit line 570 may be formed on the second insulating interlayer 540 and may be electrically connected to the first source/drain region 402a via a bit line contact 550 and the first plug 532. The bit line contact 550 may be formed through the second insulating interlayer 540; and the first plug 532 may be formed through the first insulating interlayer 540. In an implementation, the bit line 570 may extend in the second direction.

The wiring structure may include a fourth plug 682, a second wiring 710, and a diffusion barrier layer pattern 720.

The fourth plug 682 may be formed through the fourth insulating interlayer 670 and in the third insulating interlayer 600. The fourth plug 682 may be electrically connected to the first impurity region 401 via the first wiring 582 and the third plug 562. In an implementation, a plurality of fourth plugs 682 may be formed. The third plug 562 may be formed through the first and second insulating interlayers 520 and 540; and the first wiring 582 may be formed on the second insulating interlayer 540 and covered by the third insulating interlayer 600.

The second wiring 710 may be formed on the fourth plug 682 and the fourth insulating interlayer 670 and may partially fill an opening (not shown) through an etch stop layer 690 and a fifth insulating interlayer 700 (sequentially formed on the fourth insulating interlayer 670). The second wiring 710 may be electrically connected to the fourth plug 682. In an implementation, a plurality of fourth plugs 682 may be formed to correspond to the plurality of second wirings 710.

The diffusion barrier layer pattern 720 may be formed on the second wiring 710 and may fill remaining portions of the opening. A top surface of the diffusion barrier layer pattern 720 may be coplanar with a top surface of the fifth insulating interlayer 700. In an implementation, a plurality of diffusion barrier layer patterns 720 may be formed to correspond to the plurality of the second wirings 710.

The wiring structure may include the diffusion barrier layer pattern 720 formed only on the second wiring 670; and the diffusion barrier layer pattern 720 may not entirely cover the fifth insulating interlayer 700. Thus, removal of residual hydrogen in the first to fifth insulating interlayers 520, 540, 600, 670, and 700 by a heat treatment process may be facilitated so that the gate insulation layer patterns 412 and 414 of the first and second transistors, respectively, may have good interface characteristics. Also, a diffusion path via the diffusion barrier layer pattern 720 between the second wirings 160 may be blocked so that electromigration between the second wirings 710 may be reduced or prevented. Thus, a semiconductor device using the wiring structure may have good reliability.

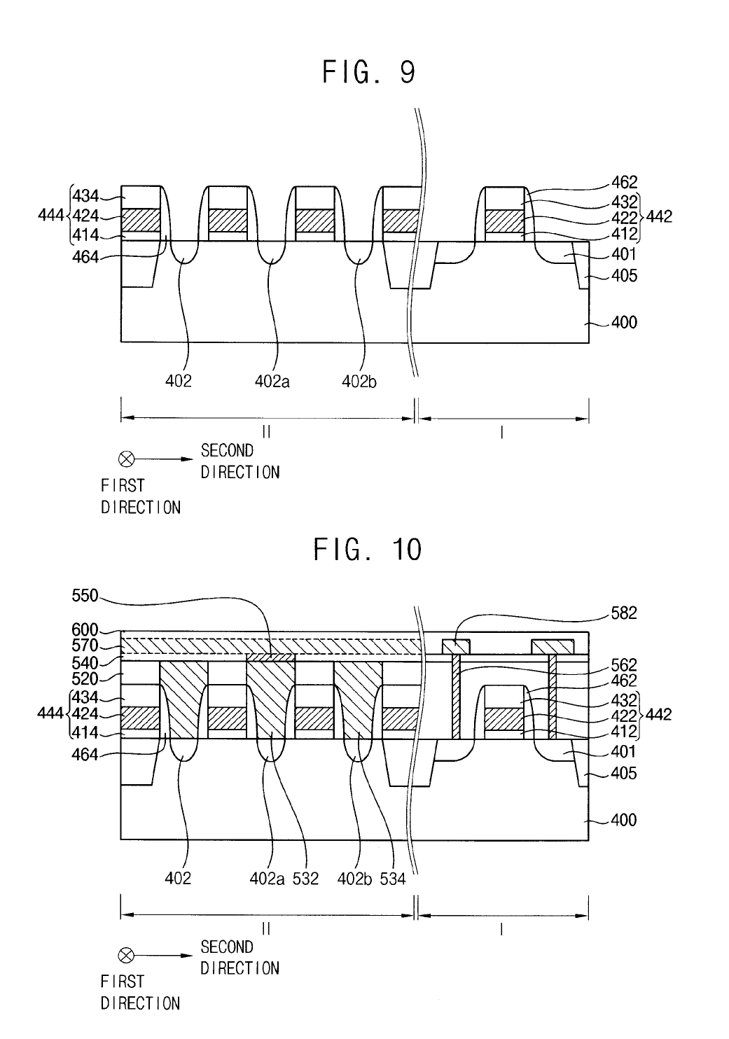

FIGS. 9 to 13 illustrate cross-sectional views of stages in a method of manufacturing the semiconductor device of FIG. 8.

Referring to FIG. 9, an isolation layer 405 may be formed on a substrate 400; and a first gate structure 442 and a second gate structure 444 may be formed on the substrate 400 in a first region I and a second region II, respectively.

The second region II may be a cell region and the first region I may be a peripheral circuit region. The peripheral circuit region may further include an NMOS transistor region and a PMOS transistor region; and a plurality of first gate structures 442 may be formed in the NMOS and PMOS transistor regions.

A gate insulation layer, a gate conductive layer, and a gate mask layer (not shown) may be sequentially formed on the substrate 400, and may be patterned by a photolithography process to form the first gate structure 442 and the second gate structure 444. Thus, the first gate structure 442 may include a first gate insulation layer pattern 412, a first gate electrode 422, and a first gate mask 432 sequentially stacked on the substrate 400 in the first region I. The second gate structure 444 may include a second gate insulation layer pattern 414, a second gate electrode 424, and a second mask 434 sequentially stacked on the substrate 400 in the second region II. In an implementation, a plurality of first and second gate structures 442 and 444 may be formed in a second direction; and each of the first and second gate structure 442 and 444 may extend in a first direction substantially perpendicular to the second direction.

A first spacer 462 and a second spacer 464 may be formed on sidewalls of the first and second gate structures 442 and 444, respectively. For example, a spacer layer (not shown) may be formed on the substrate 400 to cover the first and second gate structures 442 and 444; and the spacer layer may be partially removed by an anisotropic etching process to form the first and second spacers 462 and 464.

Impurities may be implanted at upper portions of the substrate 400 in the first and second regions I and II (using the first and second gate structures 442 and 444 and the first and second spacers 462 and 464 as an ion implantation mask) to form a first impurity region 401 and a second impurity region 402 at upper portions of the substrate 400 adjacent to the first and second gate structures 442 and 444, respectively. The second impurity region 402 may include a first source/drain region 402a and a second source/drain region 402b. In an implementation, the impurities may include n-type impurities, e.g., phosphorous or arsenic.

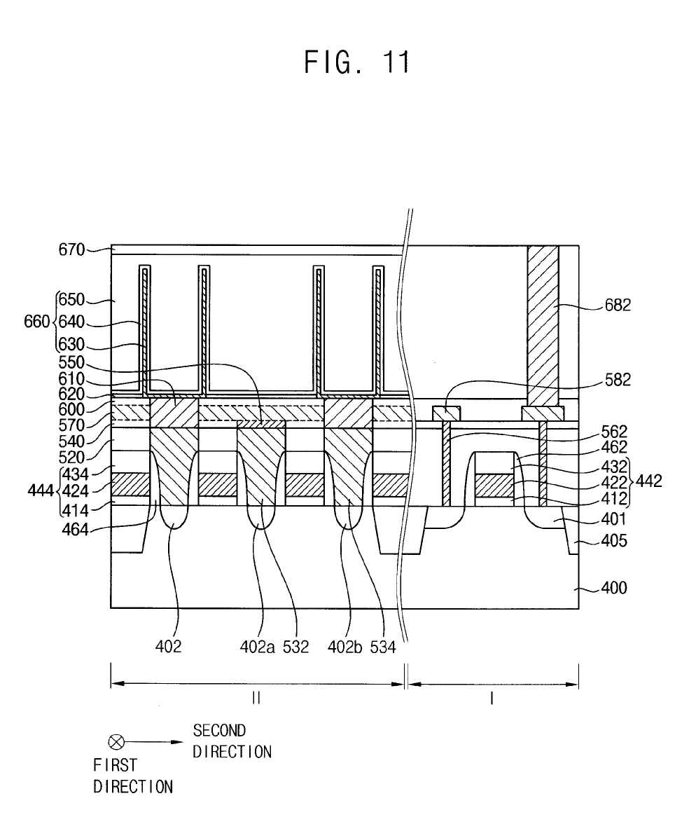

Referring to FIG. 10, a first insulating interlayer 520 may be formed on the substrate 400 to cover the gate structures 442 and 444 and the spacers 462 and 464. The first insulating interlayer 520 may be formed using an oxide, e.g., BPSG, USG, or SOG.

First openings (not shown) may be formed through the first insulating interlayer to expose the first and second source/drain regions 402a and 402b. A first conductive layer (not shown) may then be formed on the substrate 400 and the first insulating interlayer 520 to fill the first openings. The first conductive layer may be formed using, e.g., doped polysilicon, a metal, and/or a metal silicide. An upper portion of the conductive layer may be planarized until a top surface of the first insulating interlayer 520 is exposed to form a first plug 532 and a second plug 534 (electrically connected to the first source/drain region 402a and the second source/drain region 402b), respectively.

A second insulating interlayer 540 may be formed on the first insulating interlayer 520 and the first and second plugs 532 and 534. Second openings (not shown) may then be formed through the second insulating interlayer 540 and/or the first insulating interlayer 520 to expose the first plug 532 and the first impurity region 401. The second insulating interlayer 540 may be formed using an oxide, e.g., BPSG, USG, or SOG. A second conductive layer (not shown) may be formed on the substrate 400, the first plug 532, and the second insulating interlayer 540 to fill the second openings. The second conductive layer may be formed using, e.g., doped polysilicon, a metal, a metal nitride, and/or a metal silicide. An upper portion of the second conductive layer may be planarized until a top surface of the second insulating interlayer 540 is exposed to form a bit line contact 550 and a third plug 562, electrically connected to the first plug 532 and the first impurity region 401, respectively.

A third conductive layer (not shown) may be formed on the second insulating interlayer 540 to contact the bit line contact 550 and the third plug 562. The third conductive layer may be patterned to form a bit line 570 and a first wiring 582 electrically connected to the bit line contact 550 and the third plug 562, respectively. In an implementation, the bit line 570 may extend in the second direction. The third conductive layer may be formed using, e.g., doped polysilicon, a metal, a metal nitride, and/or a metal silicide.

A third insulating interlayer 600 may be formed on the second insulating interlayer 540 to cover the bit line 570 and the first wiring 582. The third insulating interlayer 600 may be formed using an oxide, e.g., BPSG, USG, or SOG.

Referring to FIG. 11, third openings (not shown) may be formed through the second and third insulating interlayers 540 and 600 to expose the second plugs 534. A fourth conductive layer (not shown) may be formed on the second plugs 534 and the third insulating interlayer 600 to fill the third openings. The fourth conductive layer may be formed using, e.g., doped polysilicon, a metal, a metal nitride, and/or a metal silicide. An upper portion of the fourth conductive layer may be planarized until a top surface of the third insulating interlayer 600 is exposed to form capacitor contacts 610 electrically connected the second plugs 534.

A first etch stop layer 620 and a mold layer (not shown) may be sequentially formed on the capacitor contacts 610 and the third insulating interlayer 600. In an implementation, the first etch stop layer 620 may be formed using silicon nitride and the mold layer may be formed using silicon oxide. Fourth openings (not shown) may be formed through the mold layer and the first etch stop layer 620 to expose the capacitor contacts 610. A fifth conductive layer (not shown) may be formed on the capacitor contacts 610, a sidewall of the fourth opening, and the mold layer; and a sacrificial layer (not shown) may be formed on the fifth conductive layer to fill remaining portions of the fourth openings. The fifth conductive layer may be formed using, e.g., doped polysilicon, a metal, a metal nitride, and/or a metal silicide. Upper portions of the sacrificial layer and the fifth conductive layer may be planarized until a top surface of the mold layer is exposed and the sacrificial layer may be removed. Thus, a lower electrode 630 may be formed on the capacitor contacts 610 and the sidewall of the fourth openings.

A dielectric layer 640 may be formed on the lower electrode 630 and the first etch stop layer 620. The dielectric layer 640 may be formed using silicon nitride or a material having a high dielectric constant, e.g., tantalum oxide, hafnium oxide, aluminum oxide, or zirconium oxide.

An upper electrode 650 may be formed on the dielectric layer 640. The upper electrode 650 may be formed using, e.g., doped polysilicon, a metal, a metal nitride, and/or a metal silicide. Thus, a capacitor 660 including the lower electrode 630, the dielectric layer 640, and the upper electrode 650 may be formed.

A fourth insulating interlayer 670 may be formed on the third insulating interlayer 600 to cover the capacitor 660. The fourth insulating interlayer 670 may be formed using an oxide, e.g., BPSG, USG, or SOG. Fifth openings (not shown) may be formed through the fourth insulating interlayer 670 and an upper portion of the third insulating interlayer 600 to expose the first wirings 582. A sixth conductive layer (not shown) may be formed on the first wirings 582 and the fourth insulating interlayer 670. An upper portion of the sixth conductive layer may be planarized until a top surface of the fourth insulating interlayer 670 is exposed to form a fourth plug 682 electrically connected to the first wirings 582.

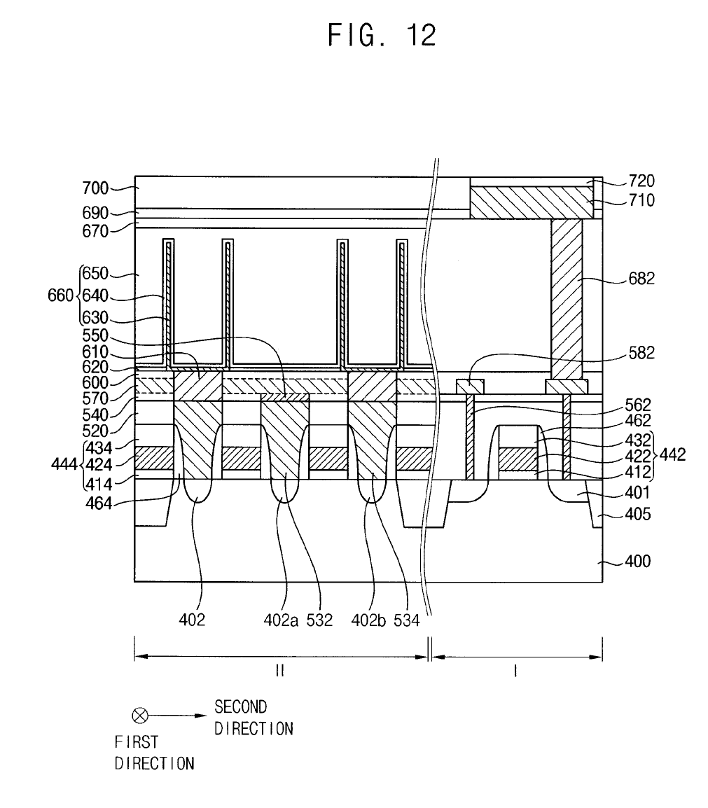

Referring to FIG. 12, processes substantially the same as or similar to those illustrated with reference to FIGS. 4 to 6 may be performed.

For example, a second etch stop layer 690 and a fifth insulating interlayer 700 may be sequentially formed on the fourth insulating interlayer 670 and the fourth plug 682; and a sixth opening (not shown) may be formed through the fifth insulating interlayer 700 and the second etch stop layer 690 to expose the fourth plug 682. In an implementation, a plurality of sixth openings may be formed.

The sixth opening in the fifth insulating interlayer 700 may be partially filled with a conductive material to form a second wiring 710 electrically connected to the fourth plug 682. In an implementation, a plurality of second wirings 710 may be formed.

A diffusion barrier layer pattern 720 may be formed on the second wiring 710 to fill remaining portions of the sixth opening. In an implementation, a plurality of diffusion barrier layer patterns 720 may be formed.

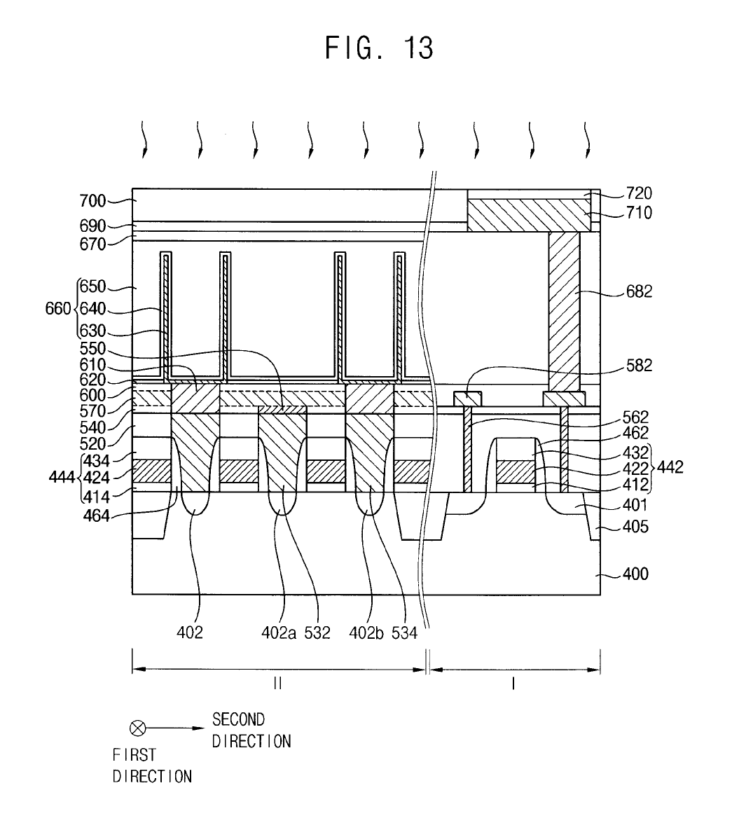

Referring to FIG. 13, a process substantially the same as or similar to that illustrated with reference to FIG. 7 may be performed.

For example, a heat treatment process may be performed on the substrate 400 including the gate structure 442 and 444, the capacitor 660, the second wiring 710, the plugs 532, 534, 562, and 682, and the insulating interlayers 520, 540, 600, 670, and 700. Thus, residual or free hydrogen in the insulating interlayers 520, 540, 600, 670, and 700 may be removed; and dangling bonds at an interface between the substrate 400 and the gate insulation layer pattern 412 and 414 may be cured.

FIG. 14 illustrates a cross-sectional view of a semiconductor device according to another embodiment.

Referring to FIG. 14, the semiconductor device may include first to third gate structures 862, 864, and 866 and first to third impurity regions 801, 803, and 805 on a substrate 800 in a first region I, and a fourth gate structure 868, a fourth impurity region 807, and a wiring structure on the substrate 800 in a second region II. The semiconductor device may further include a common source line (CSL) 882 and a bit line 900. The first region I may be a cell region and the second region II may be a peripheral circuit region.

A plurality of first gate structures 862 may be spaced apart from each other in a first direction between the second and third gate structures 984 and 868. Each first gate structure 862 may extend in a second direction substantially perpendicular to the first direction. In an implementation, sixteen or thirty-two first gate structures 862 may be formed.

The first to fourth gate structures 862, 864, 866, and 868 may include first to fourth tunnel insulation layer patterns 812, 814, 816, and 818, first to fourth floating gates 822, 824, 826, and 828, first to fourth dielectric layer patterns 832, 834, 836, and 838, first to fourth control gates 842, 844, 846, and 848, and first to fourth gate masks 852, 854, 856, and 858, respectively. First to fourth spacers 872, 874, 876, and 878 may be further formed on sidewalls of the first to fourth gate structures 862, 864, 866, and 868.

A first insulating interlayer 880 may be formed on the substrate 800 to cover the first to fourth gate structures 862, 864, 866, and 868. Second and third insulating interlayers 890 and 910 may be sequentially stacked on the first insulating interlayer 880.

The CSL 882 may be formed through the first insulating interlayer 880 and may be electrically connected to the second impurity region 803. The bit line 900 may be formed on the second insulating interlayer 890 and may be electrically connected to the third impurity region 805 via a bit line contact 884. The bit line contact 884 may be formed through the first and second insulating interlayers 880 and 890. A first plug 886 may be formed through the first and second insulating interlayer 880 and 890 and may be electrically connected to the bit line 900 and the fourth impurity region 807.

The wiring structure may include a sequentially stacked second plug 920, a wiring 950, and a diffusion barrier layer pattern 960.

The second plug 920 may be formed in the third insulating interlayer 910 and may be electrically connected to the bit line 900. In an implementation, a plurality of second plugs 920 may be formed.

The wiring 950 may partially fill an opening (not shown) formed through an etch stop layer 930 and a fourth insulating interlayer 940. The wiring 950 may be electrically connected to the second plug 920 exposed by the opening. In an implementation, a plurality of wirings 950 may be formed.

The diffusion barrier layer pattern 960 may be formed on the wiring 950 to fill remaining portions of the opening. In an implementation, a top surface of the diffusion barrier layer pattern 960 may be coplanar with a top surface of the fourth insulating interlayer 940. In an implementation, a plurality of diffusion barrier layer patterns 960 may be formed to correspond to the plurality of the wirings 950.

The wiring structure may include the diffusion barrier layer pattern 960 formed only on the wiring 950; and the diffusion barrier layer pattern 960 may not entirely cover the fourth insulating interlayer 940. Thus, removal of residual hydrogen in the first to fifth insulating interlayers 880, 890, 910, and 940 by a heat treatment process may be facilitated so that the gate insulation layer patterns 812, 814, 816, and 818 of the first to fourth gate structures 862, 864, 866, and 868 may have good interface characteristics. Also, a diffusion path via the diffusion barrier layer pattern 960 between the wirings 950 may be blocked so that electromigration between the wirings 950 may be reduced or prevented. Thus, a semiconductor device using the wiring structure may have good reliability.

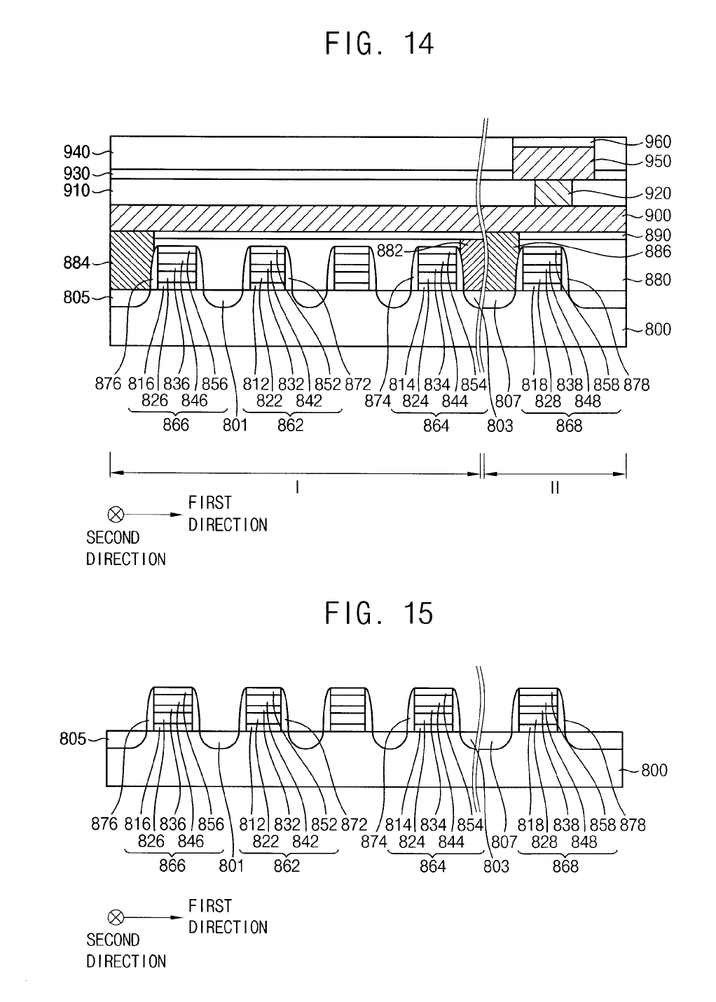

FIGS. 15 to 19 illustrate cross-sectional views of stages in a method of manufacturing the semiconductor device of FIG. 14.

Referring to FIG. 15, an isolation layer (not shown) may be formed on a substrate 800 to define an active region and a field region. First to fourth gate structures 862, 864, 866, and 868 may be formed on the substrate 800.

In an implementation, a tunnel insulation layer, a floating gate layer, a dielectric layer, and a control gate layer (not shown) may be sequentially formed on the substrate 800 and may be patterned to form first to fourth gate structures 862, 864, 866, and 868 on the substrate 800.

The first to third gate structures 862, 864, and 866 may be formed on the substrate 800 in the first region I; and the fourth gate structure 868 may be formed on the substrate 800 in the second region II. The first region I may be a cell region; and the second region II may be a peripheral circuit region. A plurality of first gate structures 862 (each extending in a second direction) may be spaced apart from each other in a first direction substantially perpendicular to the second direction between the second and third gate structures 864 and 868. In an implementation, sixteen or thirty-two first gate structures 862 may be formed.

The first to fourth gate structures 862, 864, 866, and 868 may include first to fourth tunnel insulation layer patterns 812, 814, 816, and 818, first to fourth floating gates 822, 824, 826, and 828, first to fourth dielectric layer patterns 832, 834, 836, and 838, first to fourth control gates 842, 844, 846, and 848, and first to fourth gate masks 852, 854, 856, and 858, respectively.

In an implementation, the tunnel insulation layer patterns 812, 814, 816, and 818 may have an island shape (e.g., may be isolated from each other). The floating gates 822, 824, 826, and 828 may also have an island shape (e.g., may be isolated from each other), while each of the dielectric layer patterns 832, 834, 836, and 838 may extend in the second direction.

A spacer layer (not shown) may be formed on the substrate 800 to cover the first to fourth gate structures 862, 864, 866, and 868. The spacer layer may be patterned by an anisotropic etching process to form first to fourth spacers 872, 874, 876, and 878. The spacer layer may be formed using silicon nitride.

Impurities may be implanted into upper portions of the substrate 800 (using the first to fourth gate structures 862, 864, 866, and 868 and the first to fourth spacers 872, 874, 876, and 878 as an ion implantation mask) to form first to fourth impurity regions 801, 803, 805, and 807 at upper portions of the substrate 800 adjacent to the gate structures 862, 864, 866, and 868, respectively.

The first to third control gates 842, 844, and 846 may be formed on the substrate 800 in the first region I, and may serve as a word line, a ground selection line (GSL), and a string selection line (SSL), respectively.

The tunnel insulation layer may be formed by a thermal oxidation process on the substrate 800. In an implementation, the thermal oxidation process may be performed on the substrate 800 (including silicon) to form the tunnel insulation layer including silicon oxide. In this case, dangling bonds may be generated at an interface between the substrate 800 and the tunnel insulation layer.

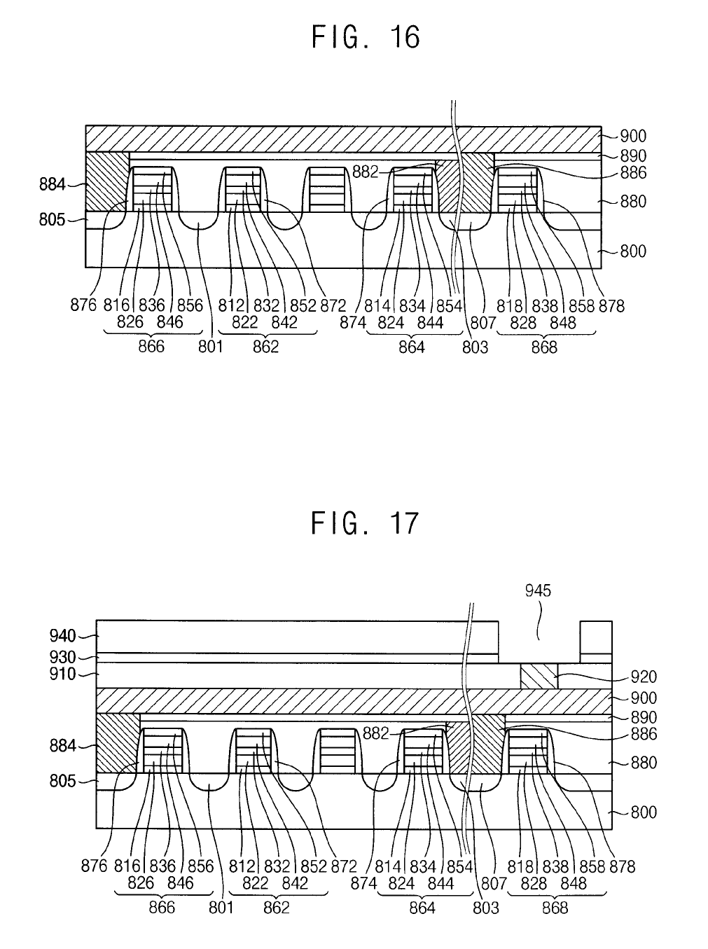

Referring to FIG. 16, a first insulating interlayer 880 may be formed on the substrate 800 to cover the gate structures 862, 864, 866, and 868. The first insulating interlayer 880 may be formed using an oxide, e.g., BPSG, USG, or SOG.

A CSL 882 may be formed through the first insulating interlayer 880 and may be electrically connected to the second impurity region 803. The CSL 882 may be formed using, e.g., doped polysilicon, a metal, a metal nitride, and/or a metal silicide.

A second insulating interlayer 890 may be formed on the first insulating interlayer 880 and the CSL 882. The second insulating interlayer 890 may be formed using an oxide, e.g., BPSG, USG, or SOG.

A bit line contact 884 may be formed through the first and second insulating interlayers 880 and 890 and may be electrically connected to the third impurity region 805. The bit line contact 884 may be formed using, e.g., doped polysilicon, a metal, a metal nitride, and/or a metal silicide. A first plug 886 may be formed through the first and second insulating interlayers 880 and 890 and may be electrically connected to the fifth impurity region 807.

A bit line 900 may be formed on the second insulating interlayer 890 and may be electrically connected to the bit line contact 884. In an implementation, the bit line 900 may extend in the first direction. The bit line 900 may be formed using, e.g., doped polysilicon, a metal, a metal nitride, and/or a metal silicide. The bit line 900 may be electrically connected to the first plug 886 in the second region II.

Referring to FIG. 17, processes substantially the same as or similar to those illustrated with reference to FIGS. 3 to 4 may be performed.

For example, a third insulating interlayer 910 may be formed on the second insulating interlayer 890 to cover the bit line 900; and a first opening (not shown) may be formed through the third insulating interlayer 910 to expose the bit line 900. A conductive layer (not shown) may be formed on the bit line 900 and the second insulating interlayer 890 to fill the first opening. An upper portion of the conductive layer may be planarized until a top surface of the second insulating interlayer 890 is exposed to form a second plug 920 electrically connected to the bit line 900. An etch stop layer 930 and a fourth insulating interlayer 940 may be sequentially formed on the second insulating interlayer 890 and the second plug 920. A second opening 945 may be formed through the fourth insulating interlayer 940 and the etch stop layer 930 to expose the second plug 920.

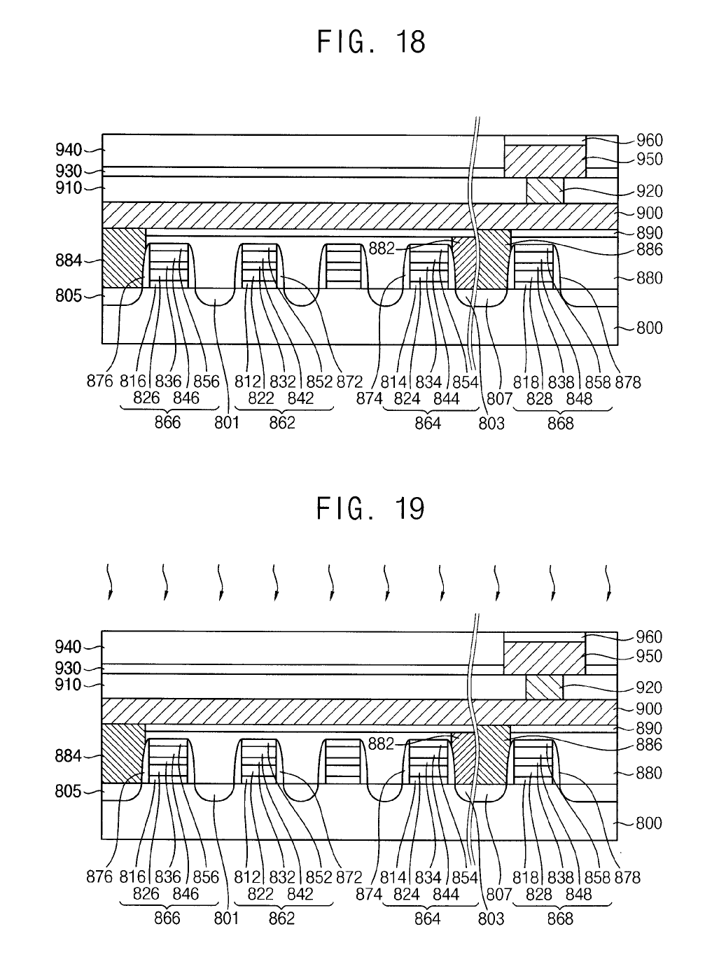

Referring to FIG. 18, processes substantially the same as or similar to those illustrated with reference to FIGS. 5 to 6 may be performed.

A wiring layer (not shown) may be formed on the second plug 920, the third insulating interlayer 910, and the fourth insulating interlayer to fill the second opening 945. An upper portion of the wiring layer may be planarized until a top surface of the fourth insulating interlayer 940 is exposed (by a CMP process or an etch-back process). An upper portion of the wiring layer may be removed to form a wiring 950 partially filling the second opening 945. A diffusion barrier layer (not shown) may be formed on the wiring 950 and the fourth insulating interlayer 940 to fill remaining portions of the second opening 945. The diffusion barrier layer may be planarized until a top surface of the fourth insulating interlayer 940 is exposed to form a diffusion barrier layer pattern 960.

Referring to FIG. 19, a process substantially the same as or similar to that illustrated with reference to FIG. 7 may be performed.

For example, a heat treatment process may be performed on the substrate 800 so that residual hydrogen in the insulating interlayers 880, 890, 910, and 940 may be removed and dangling bonds (generated at an interface between the substrate 800 and the gate insulation layer pattern 812, 814, 816, and 818) may be cured.

By the above processes, the semiconductor device may be manufactured.

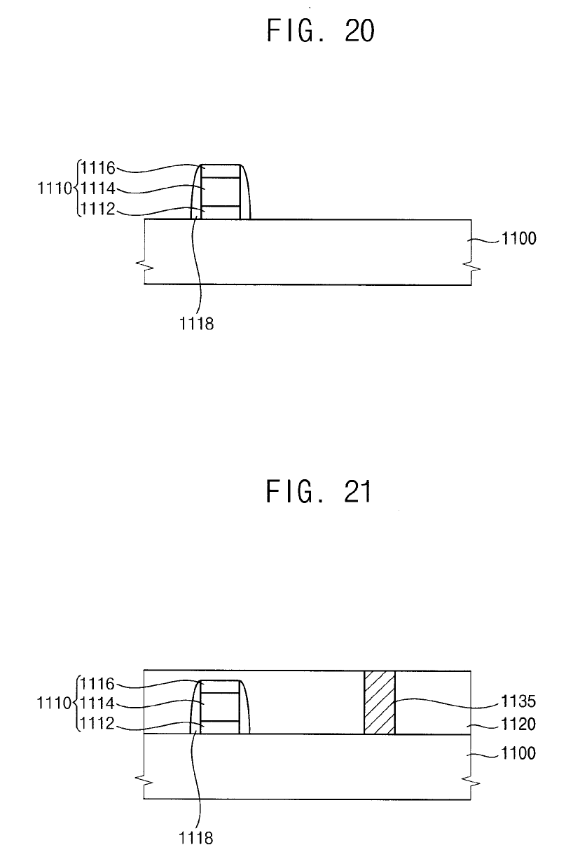

FIGS. 20 to 26 illustrate cross-sectional views of stages in a method of manufacturing a semiconductor device according to another embodiment.

Referring to FIG. 20, a gate structure 1110 may be formed on a substrate 1100. The substrate 1100 may include, e.g., a silicon substrate, a germanium substrate, a silicon-germanium substrate, a SOI substrate, a GOI substrate, or the like. An isolation layer (not shown) may be formed on the substrate 1100 to define an active region and a field region.

A gate insulation layer, a gate conductive layer, and a gate mask layer (not shown) may be formed on the substrate 1100 and may be patterned to form the gate structure 1110 including a gate insulation layer pattern 1112, a gate electrode 1114, and a gate mask 1116 sequentially stacked on the substrate 1100.

The gate insulation layer may be formed by performing a thermal oxidation process on the substrate including silicon so that dangling bonds may be formed at an interface between the substrate 1100 and the gate insulation layer. The gate conductive layer may be formed using, e.g., doped polysilicon, a metal, a metal nitride, and/or a metal silicide. The gate mask layer may be formed using, e.g., silicon nitride or silicon oxynitride.

A gate spacer 1118 may be further formed on a sidewall of the gate structure 1118. The gate spacer 1118 may be formed using silicon nitride.

Impurities may be implanted into an upper portion of the substrate 1100 (using the gate structure 1110 and the gate spacer 1118 as an implantation mask) to form an impurity region (not shown) at an upper portion of the substrate 1100 adjacent to the gate structure 1110. Thus, a transistor including the gate structure 1110 and the impurity region may be formed.

Referring to FIG. 21, a first insulating interlayer 1120 may be formed on the substrate 1100 to cover the gate structure 1110. The first insulating interlayer 1120 may be formed using, e.g., an oxide. In an implementation, the first insulating interlayer 1120 may be formed using BSG, BPSG, USG, SOG, FOX, TEOS, a HDP oxide, or HTO by a CVD process or an ALD process. When the first insulation interlayer 1120 is formed by a CVD process (using silane gas or TEOS gas as a source gas), the first insulating interlayer 1120 may include hydrogen bonds, e.g., Si—H, N-H, or Si—OH of which binding force is relatively weak. Thus, if other features of the present method are not followed, hydrogen atoms may easily migrate to the substrate 1100 or the gate insulation layer pattern 1112 so that the semiconductor device may have poor electrical characteristics.

A first opening (not shown) may be formed through the first insulating interlayer 1120 to expose the impurity region. A first conductive layer (not shown) may be formed on the substrate 1110 and the first insulating interlayer 1120 to fill the first opening. An upper portion of the first conductive layer may be planarized by a CMP process or an etch-back process to form a first plug 1135. The first plug 1135 may be formed using, e.g., doped polysilicon, a metal, and/or a metal silicide.

A barrier layer (not shown) may be further formed on a sidewall of the first opening before the first conductive layer is formed. The barrier layer may be formed using, e.g., a metal and/or a metal nitride.

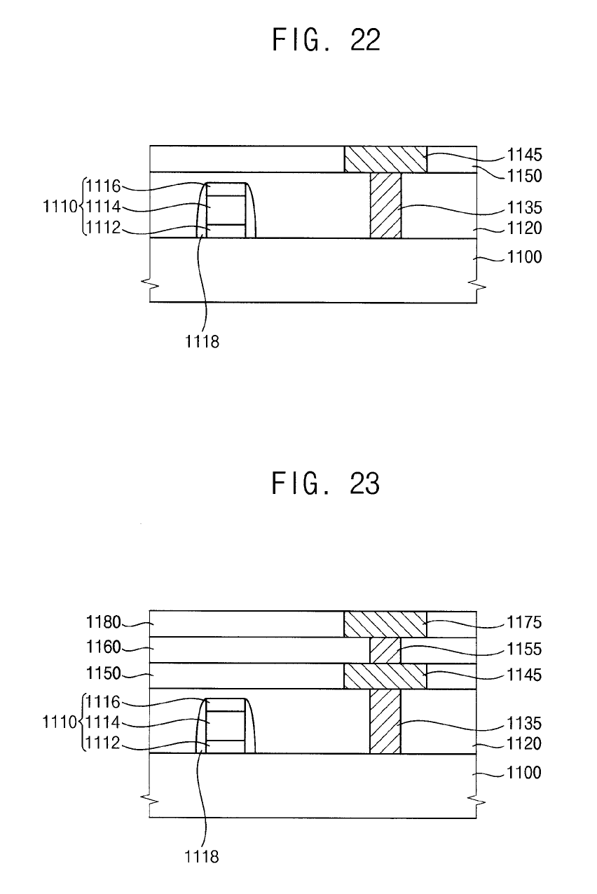

Referring to FIG. 22, a first wiring 1145 (electrically connected to the first plug 1135) may be formed on the first insulating interlayer 1120. A second insulating interlayer 1150 may be formed on the first insulating interlayer 1120 to cover a sidewall of the first wiring 1145.

For example, a second conductive layer (not shown) may be formed on the first insulating interlayer 112, and may be patterned by a photolithography process to form the first wiring 1145. The second conductive layer may be formed using, e.g., doped polysilicon, a metal, and/or a metal silicide by a CVD process, a sputtering process, or an ALD process.

An insulation layer (not shown) may be formed on the first insulating interlayer 1120 to cover the first wiring 1145. An upper portion of the insulation layer may be planarized until a top surface of the first wiring 1145 is exposed to form the second insulating interlayer 1150. The second insulating interlayer 1150 may be formed using an oxide substantially the same as or similar to that of the first insulating interlayer 1120, thereby including hydrogen bonds of which binding force is relatively weak.

Referring to FIG. 23, a third insulating interlayer 1160 may be formed on the first wiring 1145 and the second insulating interlayer 1150. A second plug 155 (contacting the first wiring 1145) may be formed through the third insulating interlayer 1160.

For example, the third insulating interlayer 1160 may be formed using an oxide by a CVD process. A second opening (not shown) may be formed through the third insulating interlayer 1160 to expose the first wiring 1145. A third conductive layer (not shown) may be formed on the first wiring 1145 and the third insulating interlayer 1160 to fill the second opening. An upper portion of the third conductive layer may be planarized until a top surface of the third insulating interlayer 1160 is exposed to form the second plug 155. The third conductive layer may be formed using, e.g., doped polysilicon, a metal, and/or a metal silicide.

A second wiring 1175 may be formed on the third insulating interlayer 1160 and may be electrically connected to the second plug 1155. In an implementation, a fourth conductive layer (not shown) may be formed on the second plug 1155 and the third insulating interlayer 1160 and may be patterned to form the second wiring 1175. The fourth conductive layer may be formed using, e.g., doped polysilicon, a metal, and/or a metal silicide.

A fourth insulating interlayer 1180 may be formed on the third insulating interlayer 1160 to cover a sidewall of the second wiring 1175. For example, an insulation layer may be formed on the third insulating interlayer 1160 to cover the second wiring 1175. An upper portion of the third insulating interlayer 1160 may be planarized until a top surface of the second wiring is exposed to form the fourth insulating interlayer 1180. The fourth insulating interlayer 1180 may be formed using an oxide.

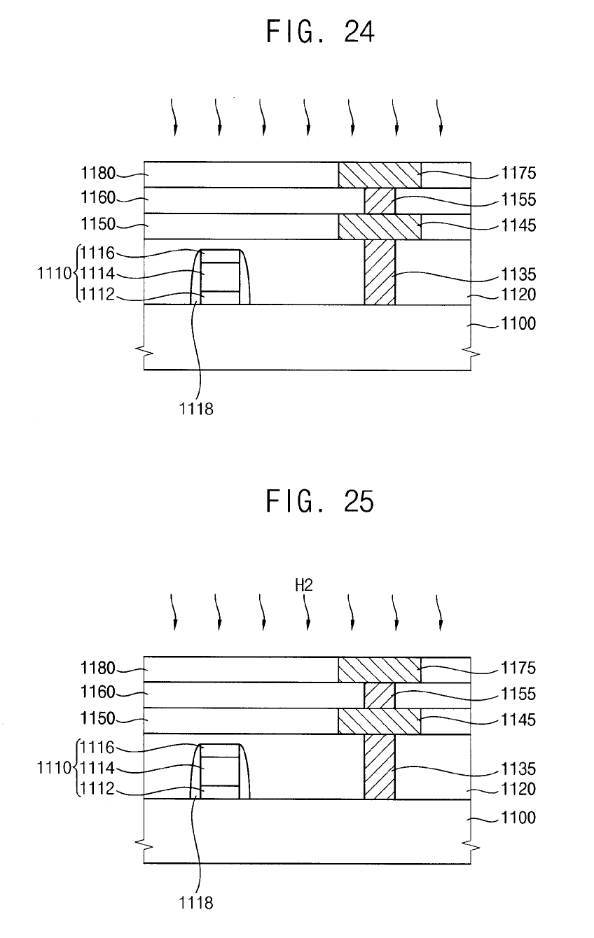

Referring to FIG. 24, a first annealing process may be performed on the substrate 1100 using a first annealing gas (which may not include hydrogen) such that residual hydrogen in the first to fourth insulating interlayers 1120, 1150, 1160, and 1180 may be removed. Thus, diffusion of residual hydrogen in the insulating interlayers 1120, 1150, 1160, and 1180 to the substrate 1100 or the gate insulation layer pattern 1112 may be reduced or prevented.

In an implementation, the first annealing process may be performed for about 1 hour to about 5 hours at a temperature of about 200° C. to about 600° C. The first annealing gas may include, e.g., an inactive or inert gas (e.g., nitrogen gas, helium gas, or argon gas), oxygen gas, nitrogen oxide gas, or carbon monoxide. The first annealing process may be performed by, e.g., a furnace annealing process, a thermal annealing process, a bake annealing process, a laser annealing process, or a rapid annealing process.

Referring to FIG. 25, a second annealing process may be performed on the substrate 1100 using a second annealing gas (which may include hydrogen) such that dangling bonds at an interface between the substrate 1100 and the gate insulation layer pattern 1112 may be cured. During the second annealing process, the dangling bonds of silicon atoms may form S—H bonds by being coupled with hydrogen.

In an implementation, the second annealing process may be performed for about 1 hour to about 5 hours at a temperature of about 200° C. to about 600° C. The second annealing gas may include, e.g., hydrogen gas, ammonia gas, or a mixture of nitrogen gas and hydrogen gas. For example, the second annealing process may be performed at a temperature of about 400° C. to about 500° C. using a mixture of nitrogen gas and hydrogen gas (which may include about 90% of nitrogen gas and about 10% of hydrogen gas).

In an implementation, the first and second annealing processes may be performed in-situ. In this case, the first annealing process may be performed using the first annealing gas (which may not include hydrogen); and then the second annealing process may be performed in the same chamber using the second annealing gas (which may include hydrogen). In an implementation, the second annealing process may be performed at a temperature substantially the same as that of the first annealing process. In another implementation, the second annealing process may be performed at a temperature lower than that of the first annealing process.

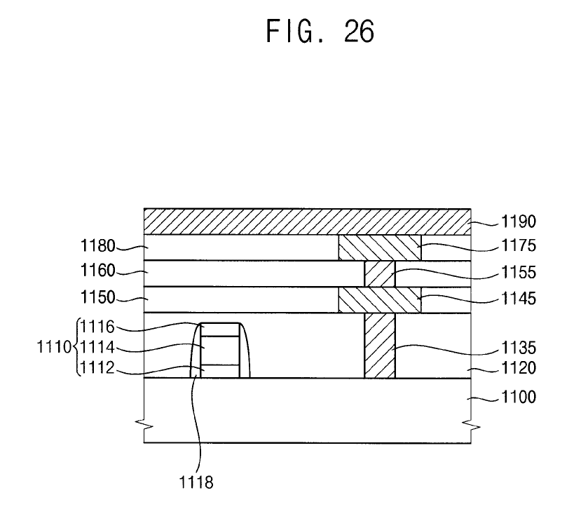

Referring to FIG. 26, a passivation layer 1190 may be further formed on the second wiring 1175 and the fourth insulating interlayer 1180. The passivation layer 1190 may serve as a protection layer for protecting the gate structure 1110 and the wirings 1145 and 1175. In an implementation, the passivation layer 1190 may be formed using, e.g., silicon nitride or a polyimide.

As shown in Table 1, below, a diffusion coefficient of hydrogen in silicon nitride may be relatively low. Thus, the passivation layer 1190 including silicon nitride may be formed after the first and second annealing processes are performed so that hydrogen may not permeate into the first to fourth insulating interlayer 1120, 1150, 1160, and 1180, the gate structure 1110, and the wirings 1145 and 1175.

TABLE 1

| | | Silicon | Silicon | | |
|---|---|---|---|---|---|
| | Silicon | oxide | nitride | copper | aluminum |
| Diffusion | 2.35 * 10⁻⁶ | 2.37 * 10⁻⁷ | 1.54 * 10⁻²⁴ | 5.14 * 10⁻⁷ | 6.88 * 10⁻⁶ |
| coefficient | | | | | |
| of H at | | | | | |
| 400° C. | | | | | |

As described above, the first annealing process may be performed using the first annealing gas (which may not include hydrogen); and the second annealing process may be performed using the second annealing gas (which may include hydrogen), so that residual hydrogen in the insulating interlayer 1120, 1150, 1160, and 1180 may be removed and dangling bonds generated at an interface between the substrate 1100 and the gate insulation layer pattern 1112 may be cured. Thus, the semiconductor device may have good electrical characteristics.

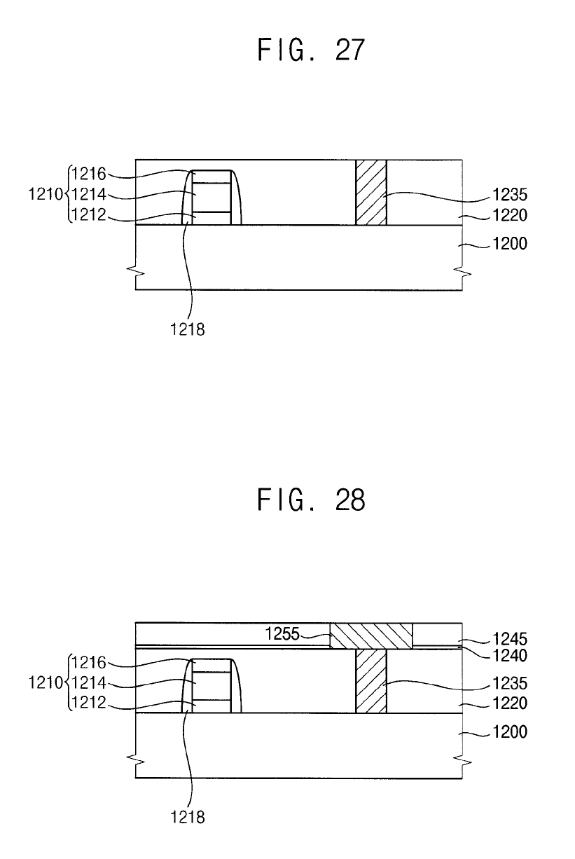

FIGS. 27 to 32 illustrate cross-sectional views of stages in a method of manufacturing a semiconductor device according to yet another embodiment. The method may be substantially the same as or similar to that illustrated with reference to FIGS. 20 to 26, except for a method of forming wirings. Thus repeated detailed explanations about the process are omitted.

Referring to FIG. 27, a gate structure 1210 may be formed on a substrate 1200. The gate structure 1210 may include a gate insulation layer pattern 1212, a gate electrode 1214, and a gate mask 1216 sequentially stacked on the substrate 1200. A gate spacer 1218 may be formed on a sidewall of the gate structure 1210.

The first insulating interlayer 1220 may be formed on the substrate 1200 to cover the gate structure 1210. The first insulating interlayer 1220 may be formed using an oxide. In an implementation, the first insulating interlayer 1220 may be formed using BSG, BPSG, USG, SOG, FOX, TEOS, a HDP oxide, HTO, or the like. The first insulating interlayer 1220 may include hydrogen bonds, e.g., Si—H, N-H or Si—OH.

The first plug 1235 may be formed on the substrate 1200 through the first insulating interlayer 1220. The first plug 1235 may be formed using, e.g., doped polysilicon, a metal, and/or a metal silicide.

Referring to FIG. 28, a first etch stop layer 1240 and a second insulating interlayer 1245 may be sequentially formed on the first insulating interlayer 1220 and the first plug 1235. A first wiring 1255 may be formed through the second insulating interlayer 1245 and the first etch stop layer 1240 to contact the first plug 1235.

In an implementation, the first etch stop layer 1240 may be formed using, e.g., silicon nitride, silicon carbide, silicon oxynitride, or silicon oxycarbide.

In an implementation, the second insulating interlayer 1245 may be formed using a material substantially the same as or similar to that of the first insulating interlayer 1220.

A second opening (not shown) may be formed through the second insulating interlayer 1245 and the first etch stop layer 1240 to expose the first plug 1235. A first conductive layer (not shown) may be formed on the first plug 1235 and the second insulating interlayer 1245 to fill the second opening. The first conductive layer may be planarized until a top surface of the second insulating interlayer 1245 is exposed to form the first wiring 1255. In an implementation, the first conductive layer may be formed using, e.g., doped polysilicon, a metal, and/or a metal silicide. For example, the metal may include copper, aluminum, or tungsten.

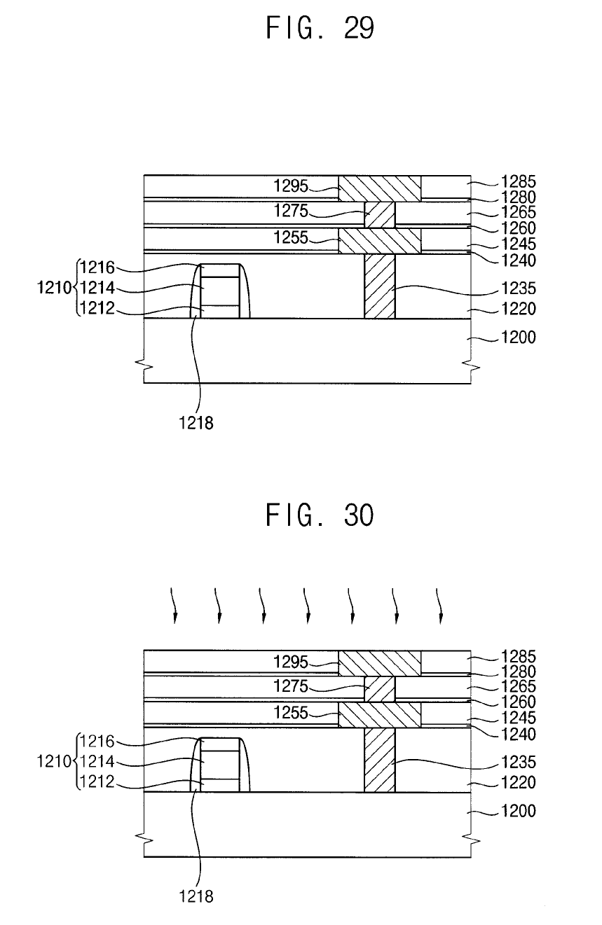

Referring to FIG. 29, a barrier layer 1260 and a third insulating interlayer 1265 may be sequentially stacked on the second insulating interlayer 1245 and the first wiring 1255. A second plug 1275 may be formed through the barrier layer 1260 and the third insulating interlayer 1265 to contact the first wiring 1255.

In an implementation, the barrier layer 1260 may be formed using, e.g., silicon nitride, silicon carbide, silicon oxynitride, or silicon oxycarbide; and the third insulating interlayer 1265 may be formed using, e.g., an oxide.

A third opening (not shown) may be formed through the third insulating interlayer 1265 and the barrier layer 1260 to expose the first wiring 1255. A third conductive layer (not shown) may be formed on the first wiring 1255 and the third insulating interlayer 1265 to fill the third opening. The third conductive layer may be planarized until a top surface of the third insulating interlayer 1265 is exposed to form the second plug 1275.

A second etch stop layer 1280 and a fourth insulating interlayer 1285 may be sequentially stacked on the third insulating interlayer 1265 and the second plug 1275. A second wiring 1295 may be formed through the second etch stop layer 1280 and the fourth insulating interlayer 1285 to contact the second plug 1275.

In an implementation, the second etch stop layer 1280 may be formed using, e.g., silicon nitride, silicon carbide, silicon oxynitride, or silicon oxycarbide; and the fourth insulating interlayer 1285 may be formed using an oxide.

A fourth opening (not shown) may be formed through the fourth insulating interlayer 1285 and the second etch stop layer 1280 to expose the second plug 1275. A fourth conductive layer (not shown) may be formed on the second plug 1275 and the fourth insulating interlayer 1285 to fill the fourth opening. The fourth conductive layer may be planarized until a top surface of the fourth insulating interlayer 1285 is exposed to form the second wiring 1295. The fourth conductive layer may be formed using, e.g., a metal (e.g., copper, aluminum, or tungsten), a metal nitride, doped polysilicon, and/or a metal silicide.

Referring to FIG. 30, a first annealing process may be performed on the substrate 1200 using a first annealing gas (which may not include hydrogen) such that residual hydrogen in the first to fourth insulating interlayers 1220, 1245, 1265, and 1285 may be removed.

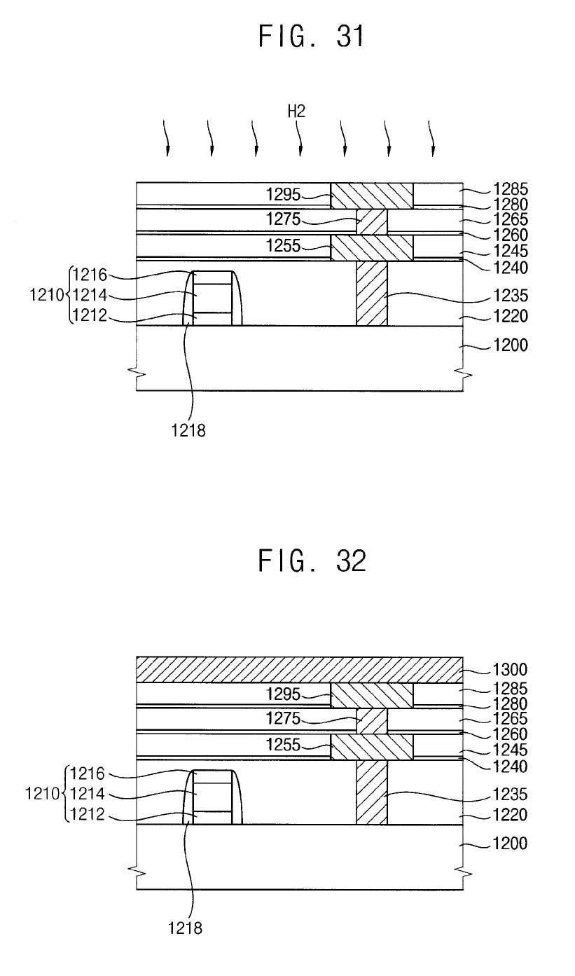

Referring to FIG. 31, a second annealing process may be performed on the substrate 1200 using a second annealing gas (which may include hydrogen) such that dangling bonds at an interface between the substrate 200 and the gate insulation layer pattern 1212 may be cured.

Referring to FIG. 32, a passivation layer 1300 may be further formed on the second wiring 1295 and the fourth insulating interlayer 1285. In an implementation, the passivation layer 1300 may be formed using, e.g., silicon nitride or polyimide.

Wirings 1255 and 1295 may be formed using copper by a damascene process; and the etch stop layers 1240 and 1280 and the barrier layer 1260 may be formed between insulating interlayers 1220, 1245, 1265, and 1285 using silicon nitride. Thus, hydrogen or hydrogen gas may not be diffused to the substrate 1200 or the gate insulation layer pattern 1212 through the insulating interlayers 1220, 1245, 1265, and 1286 during the second annealing process. However, hydrogen or hydrogen gas may be diffused to the substrate 1200 or the gate insulation layer pattern 1212 via the interface between the insulating interlayers 1220, 1245, 1265, and 1285 and the wirings 1255 and 1295 and via the interface between the insulating interlayers 1220, 1245, 1265, and 1285 and the plugs 1235 and 1275 so that dangling bonds may be cured.

FIGS. 33 to 38 illustrate cross-sectional views of stages in a method of manufacturing a semiconductor device according to still another embodiment.

Referring to FIG. 33, an isolation layer 1405 may be formed on a substrate 1400. A first gate structure 1442 and a second gate structure 1444 may be formed on the substrate 1400 in a first region I and a second region II, respectively.

The second region II may be a cell region and the first region I may be a peripheral circuit region. The peripheral circuit region may include an NMOS transistor region and a PMOS transistor region; and a plurality of first gate structures 1442 may be formed on the NMOS and PMOS transistor regions.

A gate insulation layer, a gate conductive layer, and a gate mask layer (not shown) may be sequentially formed on the substrate 1400, and may be patterned by a photolithography process to form the first gate structure 1442 and the second gate structure 1444. Thus, the first gate structure 1442 may include a first gate insulation layer pattern 1412, a first gate electrode 1422, and a first gate mask 1432 sequentially stacked on the substrate 1400 in the first region I. The second gate structure 1444 may include a second gate insulation layer pattern 1414, a second gate electrode 1424, and a second mask 1434 sequentially stacked on the substrate 1400 in the second region II. In an implementation, a plurality of first gate structures 1442 and a plurality of second gate structures 1444 may be formed in a second direction. Each first gate structure 1442 and each second gate structure 1444 may extend in a first direction substantially perpendicular to the second direction.

A first spacer 1462 and a second spacer 1464 may be formed on sidewalls of the first and second gate structures 1442 and 1444, respectively. For example, a spacer layer (not shown) may be formed on the substrate 400 to cover the first and second gate structures 1442 and 1444. The spacer layer may be partially removed by an anisotropic etching process to form the first and second spacers 1462 and 1464.

Impurities may be implanted into upper portions of the substrate 1400 in the first and second regions I and II (using the first and second gate structures 1442 and 1444 and the first and second spacers 1462 and 1464 as an ion implantation mask) to form a first impurity region 1401 and a second impurity region 1402 at upper portions of the substrate 1400 adjacent to the first and second gate structures 1442 and 1444, respectively. The second impurity region 1402 may include a first source/drain region 1402a and a second source/drain region 1402b. In an implementation, the impurities may include n-type impurities such as phosphorous or arsenic.

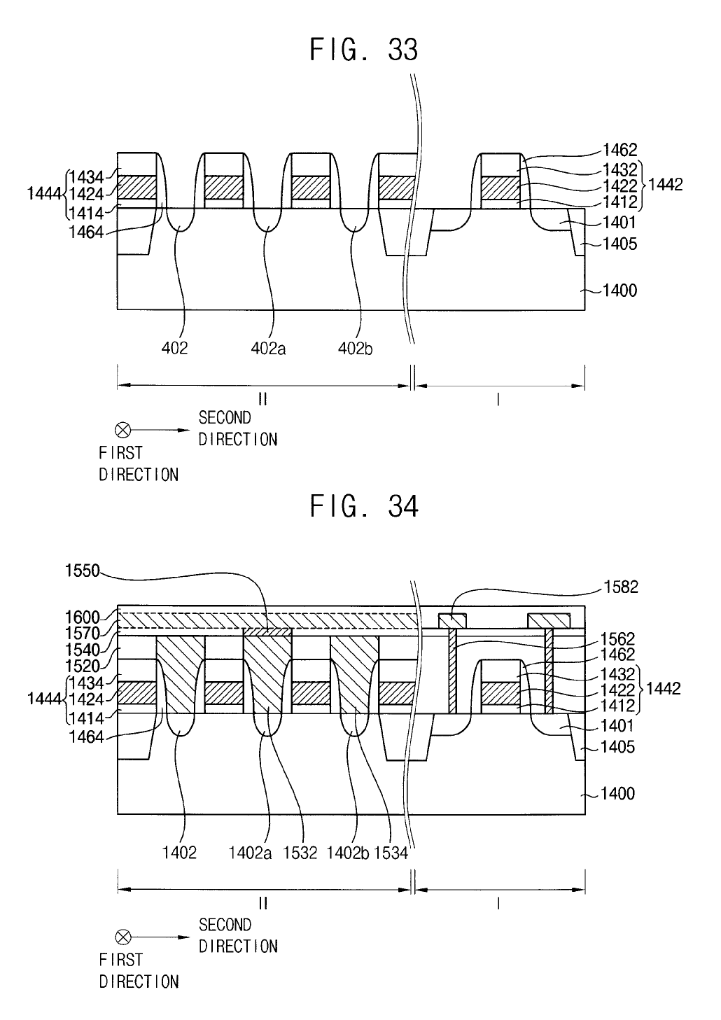

Referring to FIG. 34, a first insulating interlayer 1520 may be formed on the substrate 1400 to cover the gate structures 1442 and 1444 and the spacers 1462 and 1464. The first insulating interlayer 1520 may be formed using an oxide, e.g., BPSG, USG, or SOG.

First openings (not shown) may be formed through the first insulating interlayer to expose the first and second source/drain regions 1402a and 1402b. A first conductive layer (not shown) may be formed on the substrate 1400 and the first insulating interlayer 1520 to fill the first openings. The first conductive layer may be formed using, e.g., doped polysilicon, a metal, and/or a metal silicide. An upper portion of the conductive layer may be planarized until a top surface of the first insulating interlayer 1520 is exposed to form a first plug 1532 and a second plug 1534 electrically connected to the first source/drain region 1402a and the second source/drain region 1402b, respectively.

A second insulating interlayer 1540 may be formed on the first insulating interlayer 1520 and the first and second plugs 1532 and 1534. Second openings (not shown) may be formed through the second insulating interlayer 1540 and/or the first insulating interlayer 1520 to expose the first plug 1532 and the first impurity region 1401. The second insulating interlayer 1540 may be formed using an oxide, e.g., BPSG, USG, or SOG. A second conductive layer (not shown) may be formed on the substrate 1400, the first plug 1532, and the second insulating interlayer 1540 to fill the second openings. The second conductive layer may be formed using, e.g., doped polysilicon, a metal, a metal nitride, and/or a metal silicide. An upper portion of the second conductive layer may be planarized until a top surface of the second insulating interlayer 1540 is exposed to form a bit line contact 1550 and a third plug 1562 electrically connected to the first plug 1532 and the first impurity region 1401, respectively.

A third conductive layer (not shown) may be formed on the second insulating interlayer 1540 to contact the bit line contact 1550 and the third plug 1562. The third conductive layer may be patterned to form a bit line 1570 and a first wiring 1582 electrically connected to the bit line contact 1550 and the third plug 1562, respectively. In an implementation, the bit line 1570 may extend in the second direction. The third conductive layer may be formed using, e.g., doped polysilicon, a metal, a metal nitride, and/or a metal silicide.

A third insulating interlayer 1600 may be formed on the second insulating interlayer 1540 to cover the bit line 1570 and the first wiring 1582. The third insulating interlayer 1600 may be formed using an oxide, e.g., BPSG, USG, or SOG.

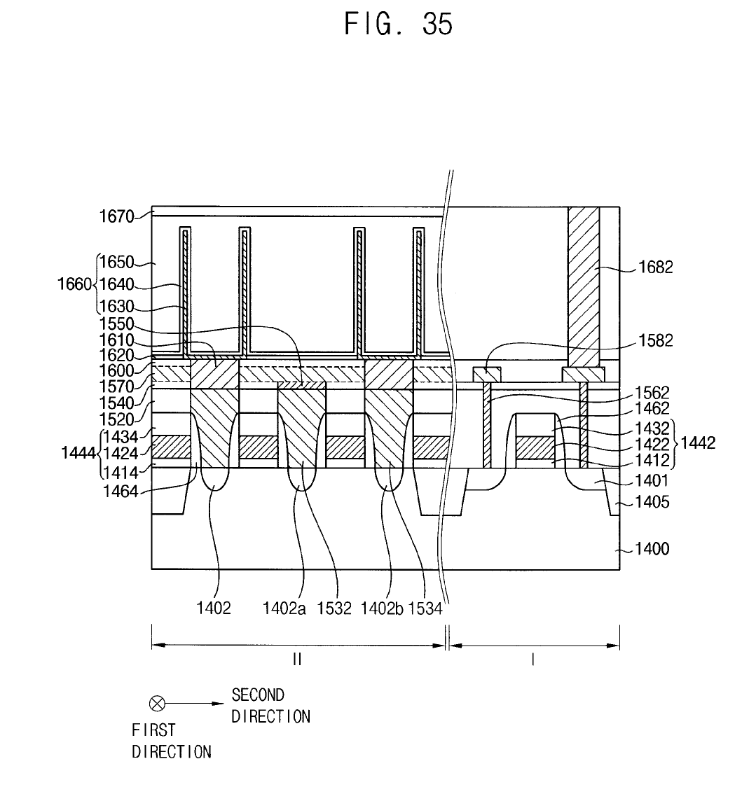

Referring to FIG. 35, third openings (not shown) may be formed through the second and third insulating interlayers 1540 and 1600 to expose the second plugs 1534. A fourth conductive layer (not shown) may be formed on the second plugs 1534 and the third insulating interlayer 1600 to fill the third openings. The fourth conductive layer may be formed using, e.g., doped polysilicon, a metal, a metal nitride, and/or a metal silicide. An upper portion of the fourth conductive layer may be planarized until a top surface of the third insulating interlayer 1600 is exposed to form capacitor contacts 1610 electrically connected the second plugs 1534.

A first etch stop layer 1620 and a mold layer (not shown) may be sequentially formed on the capacitor contacts 1610 and the third insulating interlayer 1600. In an implementation, the first etch stop layer 1620 may be formed using silicon nitride and the mold layer may be formed using silicon oxide. Fourth openings (not shown) may be formed through the mold layer and the first etch stop layer 1620 to expose the capacitor contacts 1610. A fifth conductive layer (not shown) may be formed on the capacitor contacts 1610 and the mold layer to fill the fourth openings. A sacrificial layer (not shown) may be formed on the fifth conductive layer to fill remaining portions of the fourth openings. The fifth conductive layer may be formed using, e.g., doped polysilicon, a metal, a metal nitride, and/or a metal silicide. Upper portions of the sacrificial layer and the fifth conductive layer may be planarized until a top surface of the mold layer is exposed; and the sacrificial layer may be removed. Thus, a lower electrode 1630 may be formed on the capacitor contacts 1610 and a sidewall of the fourth openings.

A dielectric layer 1640 may be formed on the lower electrode 1630 and the first etch stop layer 1620. The dielectric layer 1640 may be formed using silicon nitride or a material having a high dielectric constant, e.g., tantalum oxide, hafnium oxide, aluminum oxide, or zirconium oxide.

An upper electrode 1650 may be formed on the dielectric layer 1640. The upper electrode 1650 may be formed using, e.g., doped polysilicon, a metal, a metal nitride, and/or a metal silicide. Thus, a capacitor 1660 including the lower electrode 1630, the dielectric layer 1640, and the upper electrode 1650 may be formed.

A fourth insulating interlayer 1670 may be formed on the third insulating interlayer 1600 to cover the capacitor 1660. The fourth insulating interlayer 1670 may be formed using an oxide, e.g., BPSG, USG or SOG. Fifth openings (not shown) may be formed through the fourth insulating interlayer 1670 and an upper portion of the third insulating interlayer 1600 to expose the first wirings 1582. A sixth conductive layer (not shown) may be formed on the first wirings 1582 and the first etch stop layer 1620. An upper portion of the sixth conductive layer may be planarized until a top surface of the fourth insulating interlayer 1670 is exposed to form a fourth plug 1682 electrically connected to the first wirings 1582.

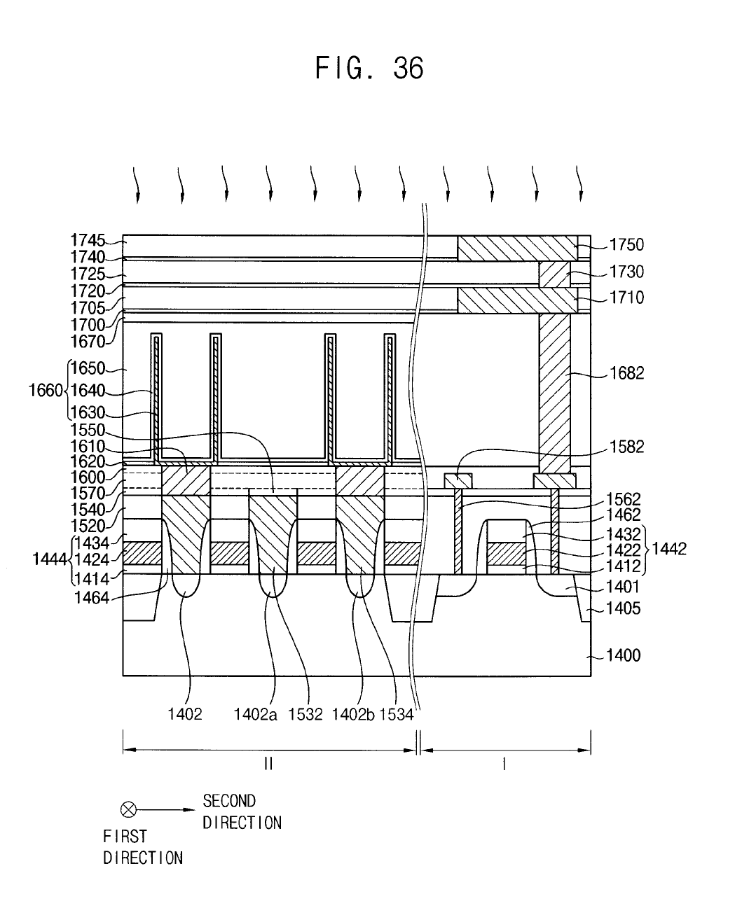

Referring to FIG. 36, processes substantially the same as or similar to those illustrated with reference to the FIGS. 23 to 25 may be performed.

For example, a second etch stop layer 1700 and a fifth insulating interlayer 1705 may be formed on the fourth insulating interlayer 1670 and the fourth plug 1682. A second wiring 1710 may be formed through the fifth insulating interlayer 1705 and the second etch stop layer 1700 to contact the fourth plug 1682.

A barrier layer 1720 and a sixth insulating interlayer 1725 may be sequentially formed on the fifth insulating interlayer 1705 and the second wiring 1710. A fifth plug 1730 may be formed through the barrier layer 1720 and the sixth insulating interlayer 1725 to contact the second wiring 1710.

A third etch stop layer 1740 and a seventh insulating interlayer 1745 may be sequentially formed on the sixth insulating interlayer 1725 and the fifth plug 1730. A third wiring 1750 may be formed through the third etch stop layer 1740 and the seventh insulating interlayer 1745 to contact the fifth plug 1730.

A first annealing process may be performed on the substrate 1400 using a first annealing gas (which may not include hydrogen), such that residual hydrogen in the first to fourth insulating interlayers 1520, 1540, 1600, 1670, 1705, 1725, and 1745 may be removed.

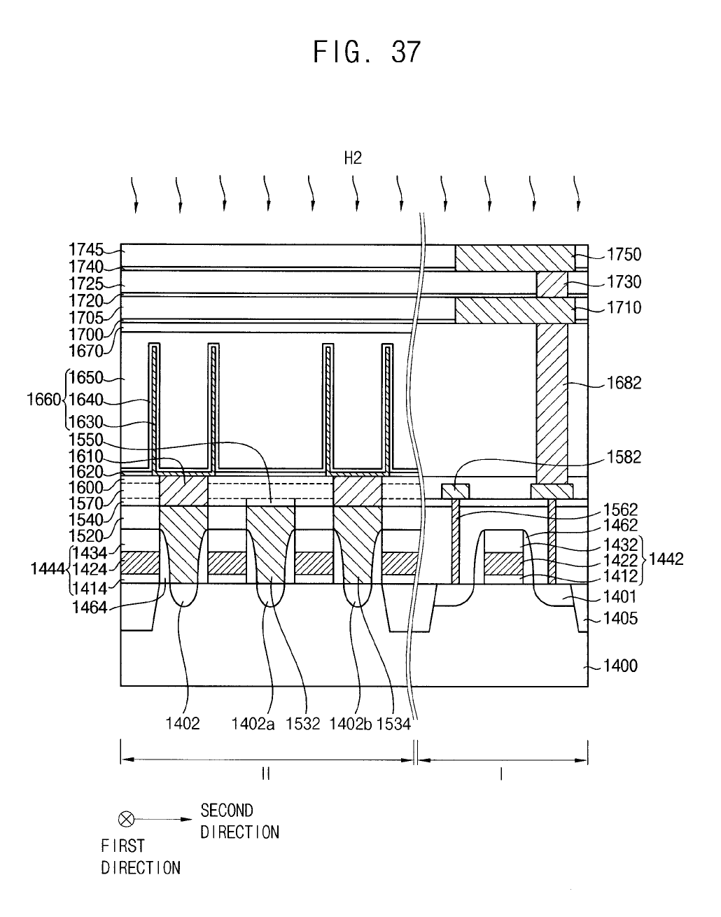

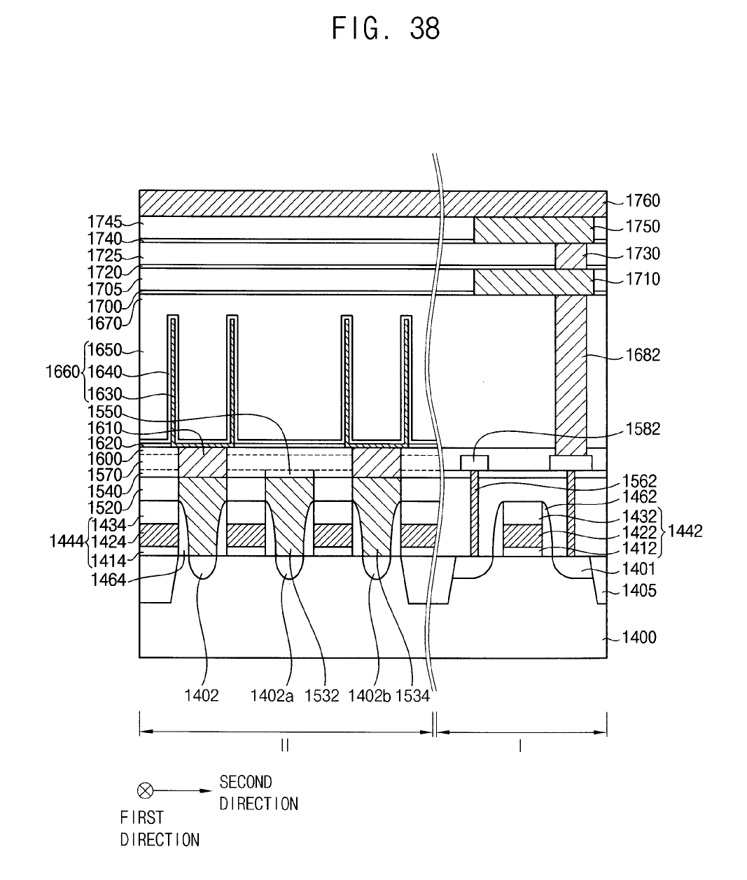

Referring to FIG. 37, a process substantially the same as or similar to that illustrated with reference to FIG. 31 may be performed.

For example, a second annealing process may be performed on the substrate 1400 using a second annealing gas (which may include hydrogen), such that dangling bonds at an interface between the substrate 1400 and the gate insulation layer patterns 1412 and 1414 may be cured.

Referring to FIG. 38, a passivation layer 1760 may be formed on the third wiring 1750 and the seventh insulating interlayer 1745 to manufacture the semiconductor device.

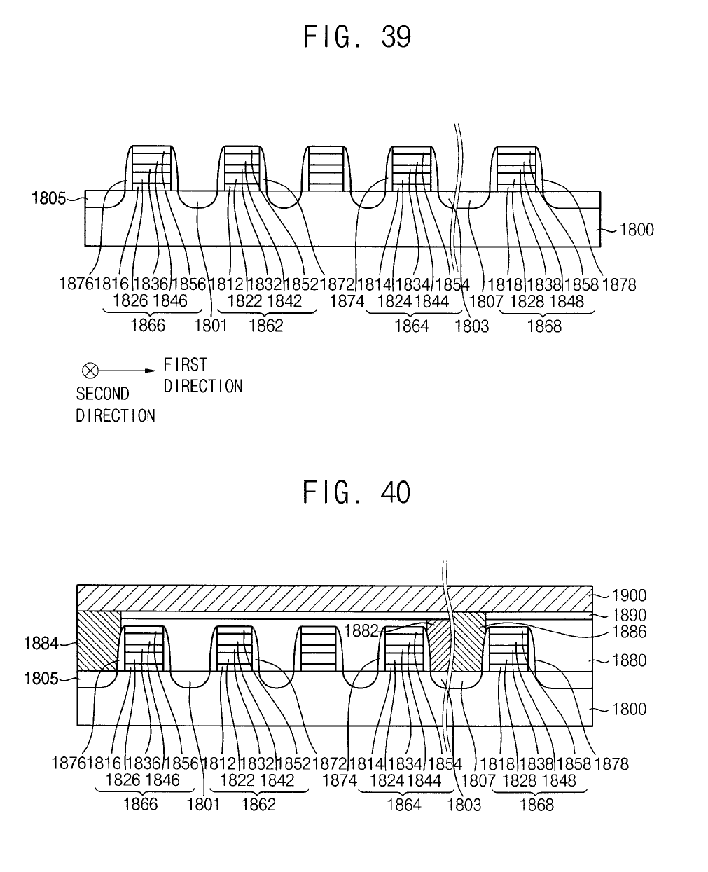

FIGS. 39 to 43 illustrate cross-sectional views of stages in a method of manufacturing a semiconductor device according to still another embodiment.

Referring to FIG. 39, an isolation layer (not shown) may be formed on a substrate 1800 to define an active region and a field region. First to fourth gate structures 1862, 1864, 1866, and 1868 may be formed on the substrate 1800.

A tunnel insulation layer, a floating gate layer, a dielectric layer and a control gate layer (not shown) may be sequentially formed on the substrate 1800 and may be patterned to form first to fourth gate structures 1862, 1864, 1866, and 1868 on the substrate 1800.

The first to third gate structures 1862, 1864, and 1866 may be formed on the substrate 1800 in the first region I. The fourth gate structure 1868 may be formed on the substrate 1800 in the second region II. The first region I may be a cell region and the second region II may be a peripheral circuit region. A plurality of first gate structures 1862 (each extending in a second direction) may be spaced apart from each other in a first direction substantially perpendicular to the second direction between the second and third gate structures 1864 and 1868. In an implementation, sixteen or thirty-two first gate structures 1862 may be formed.

The first to fourth gate structures 1862, 1864, 1866, and 1868 may include first to fourth tunnel insulation layer patterns 1812, 1814, 1816, and 1818, first to fourth floating gates 1822, 1824, 1826, and 1828, first to fourth dielectric layer patterns 1832, 1834, 1836, and 1838, first to fourth control gates 1842, 1844, 1846, and 1848, and first to fourth gate masks 1852, 1854, 1856, and 1858, respectively.

In an implementation, the tunnel insulation layer patterns 1812, 1814, 1816, and 1818 may have an island shape (e.g., isolated from each other); and the floating gates 1822, 1824, 1826, and 1828 may also have an island shape (e.g., isolated from each other). Each of the dielectric layer patterns 1832, 1834, 1836, and 1838 may extend in the second direction.

A spacer layer (not shown) may be formed on the substrate 800 to cover the first to fourth gate structures 1862, 1864, 1866, and 1868. The spacer layer may be patterned by an anisotropic etching process to form first to fourth spacers 1872, 1874, 1876, and 1878. The spacer layer may be formed using, e.g., silicon nitride.

Impurities may be implanted into upper portions of the substrate 1800 (using the first to fourth gate structures 1862, 1864, 1866, and 1868 and the first to fourth spacers 1872, 1874, 1876, and 1878 as an ion implantation mask) to form first to fourth impurity regions 1801, 1803, 1805, and 1807 at upper portions of the substrate 1800 adjacent to the gate structures 1862, 1864, 1866, and 1868, respectively.

The first to third control gates 1842, 1844, and 1846 may be formed on the substrate 1800 in the first region I and may serve as a word line, a GSL, and an SSL, respectively.

The tunnel insulation layer may be formed by a thermal oxidation process on the substrate 1800. In an implementation, the thermal oxidation process may be performed on the substrate 1800 (including silicon) to form the tunnel insulation layer including silicon oxide. In this case, dangling bonds may be generated at an interface between the substrate 1800 and the tunnel insulation layer.

Referring to FIG. 40, a first insulating interlayer 1880 may be formed on the substrate 1800 to cover the gate structures 1862, 1864, 1866, and 1868. The first insulating interlayer 1880 may be formed using an oxide, e.g., BPSG, USG, or SOG.

A CSL 1882 may be formed through the first insulating interlayer 1880 and may be electrically connected to the second impurity region 1803. The CSL 1882 may be formed using, e.g., doped polysilicon, a metal, a metal nitride, and/or a metal silicide.

A second insulating interlayer 1890 may be formed on the first insulating interlayer 1880 and the CSL 1882. The second insulating interlayer 1890 may be formed using an oxide, e.g., BPSG, USG or SOG.

A bit line contact 1884 may be formed through the first and second insulating interlayers 1880 and 1890 and may be electrically connected to the third impurity region 1805. The bit line contact 1884 may be formed using, e.g., doped polysilicon, a metal, a metal nitride, and/or a metal silicide. A first plug 886 may be formed through the first and second insulating interlayers 1880 and 1890 and may be electrically connected to the fifth impurity region 1807.

A bit line 1900 may be formed on the second insulating interlayer 1890, and may be electrically connected to the bit line contact 1884. In an implementation, the bit line 1900 may extend in the first direction. The bit line 1900 may be formed using, e.g., doped polysilicon, a metal, a metal nitride, and/or a metal silicide. The bit line 1900 may be electrically connected to the first plug 1886 in the second region II.

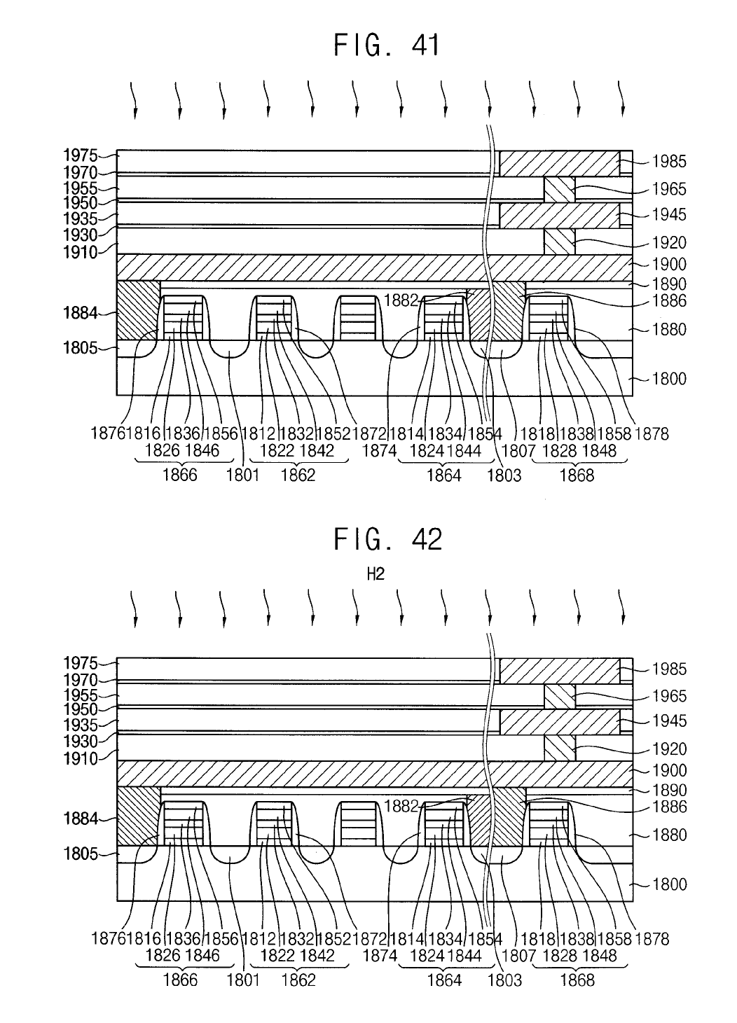

Referring to FIG. 41, processes substantially the same as or similar to those illustrated with reference to FIGS. 28 to 30 may be performed.

For example, third to seventh insulating interlayer 1910, 1935, 1955, and 1975, second to third plugs 1920 and 1965, and first and second wirings 1945 and 1985 may be formed on the second insulating interlayer 1890 and the bit line 1900.

A first annealing process may be performed on the substrate 1800 using a first annealing gas (which may not include hydrogen), such that residual hydrogen in the insulating interlayers 1880, 1890, 1910, 1935, 1955, and 1975 may be removed.

Referring to FIG. 42, a second annealing process may be performed on the substrate 1800 using a second annealing gas (which may include hydrogen), such that dangling bonds at an interface between the substrate 1800 and the gate insulation layer patterns 1812, 1814, 1816, and 1818 may be cured.

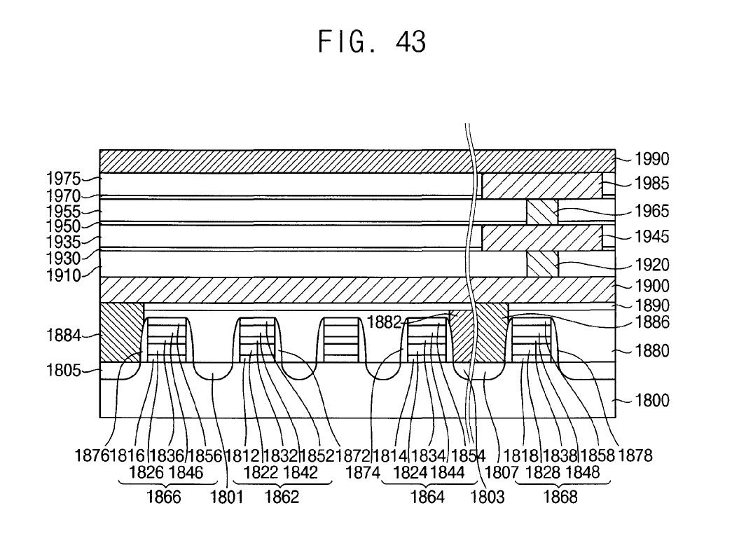

Referring to FIG. 43, a passivation layer 1990 may be formed on the second wiring 1985 and the seventh insulating interlayer 1975. Thus, the semiconductor device may be manufactured.

By way of summation and review, the silicon oxide layer may be formed by performing a thermal oxidation process on a substrate including silicon. Valence electrons of silicon atoms may not be properly bound at an interface of the substrate and the silicon oxide layer, thereby generating dangling bonds. The dangling bonds may trap drifting electrons so that a transistor including the silicon oxide layer may have an undesirably increased threshold voltage or poor data retention characteristics.

The semiconductor device may include an insulating interlayer, which may be formed using TEOS or HDP oxide by a chemical vapor deposition process. In this case, the insulating interlayer may include hydrogen bonds therein. The binding force of the hydrogen bonds is weak so that hydrogen atoms may migrate to an adjacent layer. For example, hydrogen atoms may diffuse into a gate insulation layer so that the semiconductor device may exhibit poor electrical performance.

A heat treatment process has been introduced to remove the dangling bonds and residual hydrogen. However, the heat treatment process may be difficult to perform because of some elements of the semiconductor devices, e.g., a diffusion barrier layer for preventing a migration of wiring structure.

The embodiments provide a wiring structure in which dangling bonds and residual or free hydrogen of a semiconductor device including the wiring structure may be effectively removed.

The embodiments provide a method of manufacturing a semiconductor device having good electrical characteristics.

According to the embodiments, the wiring structure may have the diffusion barrier layer pattern formed only on the wiring; and the diffusion barrier layer pattern may not entirely cover the second insulating interlayer. Thus, it may be easy to remove residual hydrogen in the insulating interlayers by a heat treatment process so that the gate insulation layer pattern of the gate structure may have good interface characteristics. Also, when a plurality of wirings is formed, a diffusion path may be extended or blocked by the diffusion barrier layer pattern so that electromigration between the wirings may be prevented. Further, a first annealing process may be performed using a first annealing gas that may not include hydrogen; and a second annealing process may be performed using a second annealing gas which may include hydrogen, so that residual hydrogen in the insulating interlayer may be removed and dangling bonds at an interface between the substrate and the gate insulation layer pattern may be cured. Thus, the semiconductor device may have good electrical characteristics.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a wiring structure, the method comprising:
forming a first insulating interlayer on a substrate;
forming a contact plug in an opening in the first insulating interlayer;
forming a second insulating interlayer on the contact plug and the first insulating interlayer;
removing a portion of the second insulating interlayer to form an opening therethrough such that the opening exposes the contact plug;
filling a portion of the opening to form a wiring such that the wiring is electrically connected to the contact plug; and
forming a diffusion barrier layer pattern on the wiring such that the diffusion barrier layer pattern fills a remaining portion of the opening.

2. The method as claimed in claim 1, further comprising forming an etch stop layer on the contact plug and the first insulating interlayer prior to forming the second insulating interlayer, wherein forming the opening includes removing a portion of the etch stop layer.

3. The method as claimed in claim 1, wherein forming the wiring includes:
forming a wiring layer on the contact plug and the second insulating interlayer to fill the opening;
planarizing the wiring layer until a top surface of the second insulating interlayer is exposed; and
removing an upper portion of the wiring layer.

4. The method as claimed in claim 1, wherein forming the diffusion barrier layer pattern includes:
forming a diffusion barrier layer on the wiring and the second insulating interlayer to fill a remaining portion of the opening; and
planarizing the diffusion barrier layer until a top surface of the second insulating interlayer is exposed.

5. The method as claimed in claim 1, wherein:
the wiring is formed using copper, and
the diffusion barrier layer pattern is formed using at least one selected from the group of silicon nitride, tantalum, titanium, tantalum nitride, and titanium nitride.

6. A method of manufacturing a semiconductor device, the method comprising:
forming a gate structure on a substrate such that the gate structure includes a sequentially stacked gate insulation layer and a gate electrode;
forming a first insulating interlayer on the substrate to cover the gate structure such that the first insulating interlayer includes hydrogen bonds therein;
performing a first annealing process using a first annealing gas to remove hydrogen in the first insulating interlayer, the first annealing gas including no hydrogen; and
performing a second annealing process using a second annealing gas to cure dangling bonds at an interface between the gate insulation layer and the substrate, the second annealing gas including hydrogen.

7. The method as claimed in claim 6, wherein the first annealing process and the second annealing process are performed at a temperature of about 200° C. to about 600° C.

8. The method as claimed in claim 6, wherein the second annealing process is performed at a temperature of about 400° C. to about 500° C.

9. The method as claimed in claim 6, wherein the second annealing process is performed at a temperature lower than a temperature at which the first annealing process is performed.

10. The method as claimed in claim 6, wherein the second annealing gas includes hydrogen (H₂) gas or ammonia (NH₃) gas.

11. The method as claimed in claim 6, wherein the first insulating interlayer is formed using at least one selected from the group of borosilicate glass, borophospho silicate glass, undoped silicate glass, spin on glass, flowable oxide, high density plasma oxide, and high-temperature oxide.

12. A method of manufacturing a wiring structure, the method comprising:
forming a first insulating interlayer on a substrate;
forming an opening in the first insulating interlayer;
forming a contact plug in the opening in the first insulating interlayer;
forming a second insulating interlayer on the contact plug and the first insulating interlayer;
forming an opening in the second insulating interlayer by removing a portion of the second insulating interlayer such that the opening exposes the contact plug;
forming a wiring by filling a portion of the opening such that the wiring is electrically connected to the contact plug;
forming a diffusion barrier layer pattern on the wiring such that the diffusion barrier layer pattern fills a remaining portion of the opening, wherein forming the diffusion barrier layer pattern includes:
forming a diffusion barrier layer on the second insulating interlayer and on the wiring, and
removing portions of the diffusion barrier layer on the second insulating interlayer and on the wiring such that a top surface of the diffusion barrier layer pattern is substantially coplanar with a top surface of the second insulating interlayer; and
removing residual hydrogen in the first and second insulating interlayers by performing a heat treatment process on the substrate including the first and second insulating interlayers thereon.

13. The method as claimed in claim 12, wherein:
the wiring is formed using copper, and
the diffusion barrier layer pattern is formed using at least one selected from the group of silicon nitride, tantalum, titanium, tantalum nitride, and titanium nitride.

14. The method as claimed in claim 12, wherein the diffusion barrier layer pattern is only on the wiring.

15. The method as claimed in claim 12, further comprising performing another heat treatment process, wherein the other heat treatment process includes a furnace annealing process, a thermal annealing process, a bake annealing process, a laser annealing process, or a rapid annealing process.
